(19) United States
(12) Patent Application Publication
(10) Pub. No.: US 2026/0150495 A1
(43) Pub. Date: May 28, 2026

(54) LIGHT-EMITTING DEVICE, DISPLAY PANEL AND DISPLAY DEVICE

(71) Applicant: Shanghai tianma Microelectronics Co., Ltd., Shanghai (CN)

(72) Inventors: Yu ZHANG, Shanghai (CN); Dongyang DENG, Shanghai (CN); Yupei ZHANG, Shanghai (CN); Ying LIU, Shanghai (CN); Min JI, Shanghai (CN); Long CHEN, Shanghai (CN)

(73) Assignee: Shanghai tianma Microelectronics Co., Ltd., Shanghai (CN)

(21) Appl. No.: 19/086,157

(22) Filed: Mar. 21, 2025

(30) Foreign Application Priority Data
Nov. 25, 2024 (CN) 202411705678.X

(51) Int. Cl. H10K 50/19; H10K 50/15; H10K 50/16; H10K 50/17; H10K 85/60; H10K 101/30

(52) U.S. Cl. CPC H10K 50/19; H10K 50/15; H10K 50/16; H10K 50/17; H10K 85/623; H10K 85/633; H10K 85/636; H10K 85/654; H10K 85/656; H10K 85/6572; H10K 85/6574; H10K 85/6576; H10K 85/658; H10K 2101/30

(57) ABSTRACT

The present application relates to a light-emitting device, a display panel and a display device. The light-emitting device comprises an anode, a cathode, and a first light-emitting unit and a second light-emitting unit which are located between the anode and the cathode, and at least one charge generation layer located between the first light-emitting unit and the second light-emitting unit, the charge generation layer comprising an N-type charge generation sub-layer and a P-type charge generation sub-layer located on a side of the N-type charge generation sub-layer close to the cathode, wherein the P-type charge generation sub-layer comprises a hole transport material, and a first hole injection material and a second hole injection material which are doped into the hole transport material, an absolute value of a lowest unoccupied molecular orbital energy level of the second hole injection material being less than that of the first hole injection material.

### CROSS-REFERENCE TO RELATED APPLICATION

This application claims priority to Chinese Patent Application No. 202411705678.X, filed on Nov. 25, 2024, which is hereby incorporated by reference in its entirety.

### TECHNICAL FIELD

The present application relates to the field of display technologies, and particularly to a light-emitting device, a display panel and a display device.

### BACKGROUND

As a new generation of display technologies, the organic electroluminescent materials (OLEDs) have been widely applied in industries such as flat panel displays, flexible displays, solid-state lighting, and vehicle-mounted displays due to their advantages of ultra-thin profiles, self-luminescence, wide viewing angles, fast response, high luminous efficiency, good temperature adaptability, simple production process, low driving voltage, and low energy consumption, etc. Tandem OLED devices are an effective approach to improve the efficiency and lifetime of OLEDs, specifically by vertically stacking two or more light-emitting units to form a single device, with the light-emitting units being connected via a charge generation layer. Compared to conventional OLEDs, the tandem OLEDs exhibit higher luminous brightness and current efficiency, both of which increase proportionally with the number of series-connected light-emitting units. However, the tandem OLEDs have the problems of high driving voltage and low luminous efficiency in the light-emitting devices. Therefore, there is still a need for further improvements in the performance of tandem OLED devices.

### SUMMARY

According to a first aspect, embodiments of the present application provide a light-emitting device, comprising: an anode, a cathode, a first light-emitting unit and a second light-emitting unit located between the anode and the cathode, and
at least one charge generation layer located between the first light-emitting unit and the second light-emitting unit, the charge generation layer including a P-type charge generation sub-layer and an N-type charge generation sub-layer, with the P-type charge generation sub-layer located on a side of the N-type charge generation sub-layer close to the cathode,
the P-type charge generation sub-layer comprising a hole transport material, and a first hole injection material and a second hole injection material doped into the hole transport material, and an absolute value of a lowest unoccupied molecular orbital energy level of the second hole injection material being less than that of the first hole injection material.

According to a second aspect, embodiments of the present application further provide a display panel comprising the light-emitting device according to the first aspect.

According to a third aspect, embodiments of the present application further provide a display device comprising the display panel according to the second aspect.

### BRIEF DESCRIPTION OF THE DRAWINGS

In order to more clearly explain the technical solutions of the embodiments of the present application or the conventional technologies, the accompanying drawings required for the embodiments of the present application or the conventional technologies will be briefly introduced below. Apparently, these drawings described below are merely some embodiments of the present application, and those skilled in the art may still derive other drawings from these accompanying drawings without requiring creative efforts.

FIG. 1 is a schematic structural diagram of a light-emitting device according to some embodiments of the present application.

FIG. 2 is another schematic structural diagram of a light-emitting device according to some embodiments of the present application.

FIG. 3 is yet another schematic structural diagram of a light-emitting device according to some embodiments of the present application.

FIG. 4 is yet another schematic structural diagram of a light-emitting device according to some embodiments of the present application.

FIG. 5 is yet another schematic structural diagram of a light-emitting device according to some embodiments of the present application.

FIG. 6 is a schematic diagram of energy level of an existing light-emitting device.

FIG. 7 is a schematic diagram of energy level of a light-emitting device according to some embodiments of the present application.

FIG. 8 is a schematic structural diagram of a display panel according to some embodiments of the present application.

FIG. 9 is a schematic structural diagram of a display device according to some embodiments of the present application.

FIG. 10 is a schematic structural diagram of a substrate used for leakage current testing according to some embodiments of the present application.

### REFERENCE NUMERALS

display device 300, display panel 200, light-emitting device 100, anode 101, cathode 102, first light-emitting unit 10, second light-emitting unit 20, charge generation layer 30, P-type charge generation sub-layer 32, N-type charge generation sub-layer 31, first intermediate sub-layer 33, second intermediate sub-layer 34, highest occupied molecular orbital energy level of N-type charge generation sub-layer NCGL_HOMO, lowest unoccupied molecular orbital energy level of N-type charge generation sub-layer NCGL_LUMO, highest occupied molecular orbital energy level of first hole injection material PD1_HOMO, lowest unoccupied molecular orbital energy level of first hole injection material PD1_LUMO, highest occupied molecular orbital energy level of second hole injection material PD2_HOMO, lowest unoccupied molecular orbital energy level of second hole injection material PD2_LUMO, highest occupied molecular orbital energy level of hole transport material HT_HOMO included in P-type charge generation sub-layer, lowest unoccupied molecular orbital energy level of hole transport material HT_LUMO included in P-type charge generation sub-layer, hole injection layer 12, first hole transport layer 13, first emission layer 14, first hole blocking layer 15, first electron transport layer 16, second hole transport layer 22, second emission layer 23, second hole blocking layer 24, second electron transport layer 25, electron injection layer 26, capping layer 41, deposition area 700, hollow area 800.

### DETAILED DESCRIPTION

To facilitate the understanding of the present application, the present application will be described more comprehensively below with reference to the relevant accompanying drawings. The drawings illustrate preferred embodiments of the present application. However, the present application can be implemented in many different forms and is not limited to the embodiments described herein. On the contrary, the purpose of providing the embodiments is to make the understanding of the disclosure of the present application more thorough and comprehensive.

Unless otherwise defined, all technical and scientific terms as used herein have the same meanings as commonly understood by those skilled in the technical field to which the present application pertains. The terms used in the description of the present application herein are merely for the purpose of describing embodiments, rather than limiting the present application. The term “and/or” as used herein includes any and all combinations of one or more relevant listed items.

When describing the positional relationship, unless otherwise specified, when an element such as a layer, a film or a substrate is referred to as being “on” another element, it may be directly on the other element, or there may be one or more intermediate elements. Furthermore, when a layer is referred to as being “under” another layer, it may be directly under the other layer, or there may be one or more intermediate elements. It can also be understood that when a layer is referred to as being “between” two layers, it may be the only layer between the two layers, or there may be one or more intermediate elements.

In a case where “comprise”, “have”, “include” or variations thereof are used herein, unless explicitly limited by terms such as “only,” “consisting of . . . ” etc., another part may be added. Unless specified to the contrary, the singular terms may include their plural forms and should not be construed to be one in number.

It should be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present application.

It should also be understood that when interpreting the elements, although not explicitly described, the elements are interpreted as including an error range, and the error range should be within a deviation range acceptable for a specific value as determined by those skilled in the art. For example, “about,” “approximately,” or “substantially” may mean within one or more standard deviations, which are not limited herein.

Furthermore, in the description, the phrase “schematic plan view” refers to a drawing drawn by viewing an object portion from the top, and the phrase “cross-sectional view” refers to a drawing drawn by viewing a section obtained by vertically cutting the object portion from the side.

In addition, the drawings are not drawn to a 1:1 scale, and the relative dimensions of the respective elements are drawn in the drawings only as examples, and are not necessarily to true proportions.

It should be noted that the embodiments of the present application and the features in the embodiments may be mutually combined without conflict. The present invention will be described in detail below with reference to the drawings and in conjunction with the embodiments.

As described in the background section, the tandem OLEDs in the prior art have the problems of high driving voltage and low luminous efficiency in the light-emitting devices. The inventors have found the cause of the above phenomenon, that is, in the tandem light-emitting devices (tandem device structures) in the prior art, the charge generation layer (CGL) typically uses a doped film layer with organic materials to achieve carrier generation and separation, but due to the inherent characteristics of the charge generation layer material and poor energy level matching of the charge generation layer and the adjacent layers, the charge generation layer in the prior art exhibits strong lateral charge transport capability and significant lateral leakage current, which necessitates a higher driving voltage to achieve the desired brightness, thereby reducing the luminous efficiency of the light-emitting devices.

It should be noted that values of the highest occupied molecular orbital energy level (HOMO energy level) and the lowest unoccupied molecular orbital energy level (LUMO energy level) mentioned herein can be calculated using Gaussian software. Herein, the larger absolute values of the “HOMO” and “LUMO” energy levels indicate the deeper energy levels.

It should be noted that the electron mobility mentioned in the present application can be measured using the space-charge limited current method.

Based on this, the inventors have further developed the technical solutions of the embodiments of the present application. Specifically, the light-emitting device according to the embodiments of the present application comprises a charge generation layer which comprises a P-type charge generation sub-layer and an N-type charge generation sub-layer, the P-type charge generation sub-layer being located on a side of the N-type charge generation sub-layer close to the cathode. The P-type charge generation sub-layer comprises a hole transport material, and a first hole injection material and a second hole injection material doped into the hole transport material. An absolute value of a lowest unoccupied molecular orbital energy level of the second hole injection material is less than that of the first hole injection material. In the present application, the first hole injection material and the second hole injection material are doped into the P-type charge generation sub-layer, and the absolute value of the lowest unoccupied molecular orbital energy level of the second hole injection material is less than that of the first hole injection material, enabling the P-type charge generation sub-layer to have multiple energy levels. Firstly, the multiple energy levels in the P-type charge generation sub-layer can match well the energy levels of adjacent film layers, providing more channels (multi-stage carrier separation channels) for charge migration. The P-type charge generation sub-layer also exhibits stronger charge separation capability, improving the charge transport rate between the first light-emitting unit and the second light-emitting unit and reducing the lateral charge transport capability of the charge generation layer. Hence, a lower driving voltage is required to drive the light-emitting device, thereby enhancing the luminous efficiency of the light-emitting device. Secondly, the hole transport material included in the P-type charge generation sub-layer exhibits stronger π-π interactions with the first hole injection material and the second hole injection material, thereby lowering the driving voltage of the device.

The above is the core idea of the present application. The technical solutions in the embodiments of the present application will be described clearly and comprehensively below in conjunction with the accompanying drawings in the embodiments of the present application. Based on the embodiments of the present application, all other embodiments achieved by those having ordinary skill in the art without creative effort fall within the scope of protection of the present application.

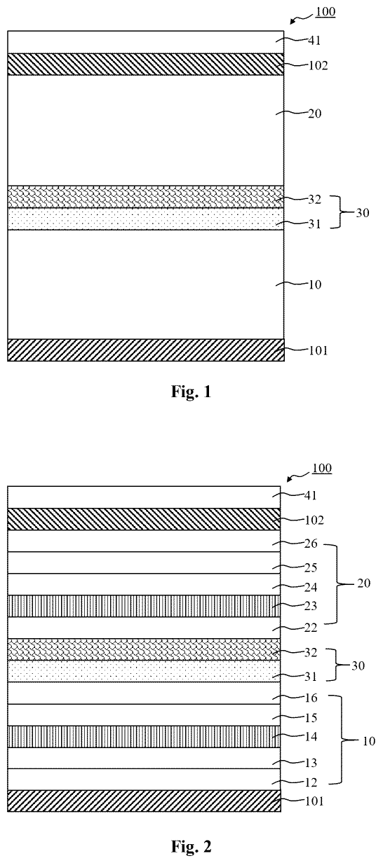

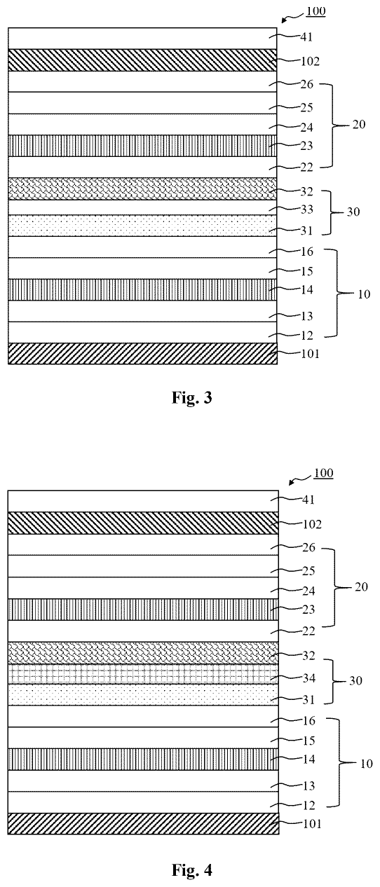

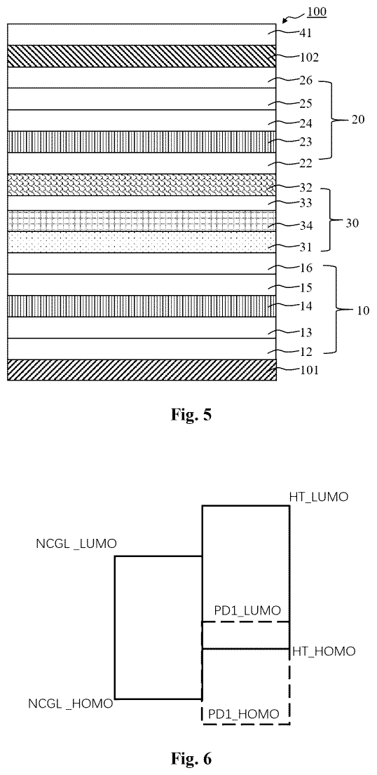

Please refer to FIGS. 1 to 5. FIG. 1 is a schematic structural diagram of a light-emitting device according to some embodiments of the present application. FIG. 2 is another schematic structural diagram of a light-emitting device according to some embodiments of the present application. FIG. 3 is another schematic structural diagram of a light-emitting device according to some embodiments of the present application. FIG. 4 is another schematic structural diagram of a light-emitting device according to some embodiments of the present application. FIG. 5 is another schematic structural diagram of a light-emitting device according to some embodiments of the present application. FIG. 1 illustrates a simple structure of the first light-emitting unit and the second light-emitting unit, FIGS. 2 to 5 exemplify detailed structures of the first light-emitting unit and the second light-emitting unit, but the detailed structures of the first light-emitting unit and the second light-emitting unit are not limited to the examples in FIGS. 2 to 5. FIGS. 2 to 5 also illustrate embodiments of different structures of the charge generation layer.

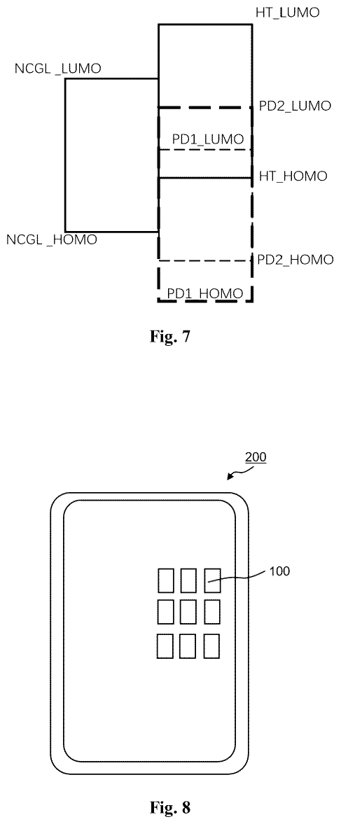

Please refer to FIGS. 6 and 7. FIG. 6 is a schematic diagram of an energy level of an existing light-emitting device. FIG. 7 is a schematic diagram of an energy level of a light-emitting device according to some embodiments of the present application.

The present application provides a light-emitting device 100. As shown in FIG. 1 and FIG. 2, the light-emitting device 100 comprises an anode 101, a cathode 102, and a first light-emitting unit 10 and a second light-emitting unit 20 located between the anode 101 and the cathode 102. The light-emitting device 100 further comprises at least one charge generation layer 30, which is located between the first light-emitting unit 10 and the second light-emitting unit 20. The charge generation layer 30 comprises a P-type charge generation sub-layer 32 and an N-type charge generation sub-layer 31, the P-type charge generation sub-layer 32 being located on a side of the N-type charge generation sub-layer 31 close to the cathode 102. The P-type charge generation sub-layer 32 comprises a hole transport material, and a first hole injection material and a second hole injection material doped into the hole transport material, and the absolute value of the lowest unoccupied molecular orbital energy level of the second hole injection material is less than that of the first hole injection material.

For example, the charge generation layer (CGL) 30 comprises a P-type charge generation sub-layer (PCGL) 32 and an N-type charge generation sub-layer (NCGL) 31. The P-type charge generation sub-layer (PCGL) 32 can generate holes, while the N-type charge generation sub-layer (NCGL) 31 can generate electrons. Driven by the voltage applied between the anode 101 and the cathode 102, the charge generation layer (CGL) 30 can generate holes and electrons to excite each light-emitting unit (the first light-emitting unit 10 and the second light-emitting unit 20) to emit light.

For example, FIGS. 6 and 7 illustrate the highest occupied molecular orbital energy level of the N-type charge generation sub-layer 31 (NCGL_HOMO), the lowest unoccupied molecular orbital energy level of the N-type charge generation sub-layer 31 (NCGL_LUMO), the highest occupied molecular orbital energy level of the first hole injection material (PD1_HOMO), the lowest unoccupied molecular orbital energy level of the first hole injection material (PD1_LUMO), the highest occupied molecular orbital energy level of the second hole injection material (PD2_HOMO), the lowest unoccupied molecular orbital energy level of the second hole injection material (PD2_LUMO), the highest occupied molecular orbital energy level of the hole transport material (HT_HOMO) included in the P-type charge generation sub-layer 32, and the lowest unoccupied molecular orbital energy level of the hole transport material (HT_LUMO) included in the P-type charge generation sub-layer 32. In FIG. 6, for ease of comparison between the present application and related technologies, an example in which the P-type charge generation sub-layer (PCGL) 32 includes only the first hole injection material is provided.

In the embodiment of the present application, the P-type charge generation sub-layer 32 comprises a hole transport material, and a first hole injection material and a second hole injection material doped into the hole transport material. The absolute value of the lowest unoccupied molecular orbital energy level of the second hole injection material is less than that of the first hole injection material. Please compare FIG. 6 and FIG. 7. As shown in FIG. 6, in the prior art, it is difficult to match the energy level of the charge generation layer 30 and the energy levels of the film layers of the light-emitting units on both sides of the charge generation layer 30 since the number of the energy levels of charge generation layer 30 is relatively limited. As shown in FIG. 7, in the present application, the first hole injection material and the second hole injection material are doped into the P-type charge generation sub-layer 32, and the absolute value of the lowest unoccupied molecular orbital energy level of the second hole injection material is less than that of the first hole injection material, enabling the P-type charge generation sub-layer 32 to have multiple energy levels. Firstly, the multiple energy levels in the P-type charge generation sub-layer 32 can well match the energy levels of adjacent film layers, providing more channels (multi-stage carrier separation channels) for charge migration. The P-type charge generation sub-layer 32 also exhibits stronger charge separation capability, improving the charge transport rate between the first light-emitting unit 10 and the second light-emitting unit 20. Hence, a lower driving voltage is required to drive the light-emitting device 100, thereby enhancing the luminous efficiency. Secondly, the hole transport material included in the P-type charge generation sub-layer 32 exhibits stronger π-π interactions with the first hole injection material and the second hole injection material, thereby lowering the driving voltage of the device. The subsequent experimental data and the analysis result 1 of the embodiments also demonstrate that the embodiments of the present application achieve a lower operating voltage and a higher current efficiency, indicating that the technical solution of the application can enhance the performance of the device and is thus expected to significantly lower the power consumption of the device.

In some embodiments, the absolute value of the lowest unoccupied molecular orbital energy level of the second hole injection material is less than or equal to 4.8 eV; and/or, the absolute value of the lowest unoccupied molecular orbital energy level of the first hole injection material is greater than or equal to 4.8 eV.

For example, as verified by the inventors, when the absolute value of the lowest unoccupied molecular orbital energy level of the second hole injection material is less than or equal to 4.8 eV, and/or, when the absolute value of the lowest unoccupied molecular orbital energy level of the first hole injection material is greater than or equal to 4.8 eV, it is possible for the P-type charge generation sub-layer 32 to have multiple energy levels, which can well match the energy levels of the adjacent film layers on both sides of the P-type charge generation sub-layer 32.

For example, the absolute value of the lowest unoccupied molecular orbital energy level of the second hole injection material is less than or equal to 4.8 eV. For example, the absolute value of the lowest unoccupied molecular orbital energy level of the second hole injection material is any one of 4.8 eV, 4.5 eV, 4.2 eV, 4.0 eV, 3.8 eV and 3.5 eV.

For example, the absolute value of the lowest unoccupied molecular orbital energy level of the first hole injection material is greater than or equal to 4.8 eV. For example, the absolute value of the lowest unoccupied molecular orbital energy level of the first hole injection material is any value of 4.8 eV, 5 eV, 5.2 eV, 5.5 eV, 5.8 eV and 6 eV.

In some embodiments, the absolute value of the difference between the lowest unoccupied molecular orbital energy level of the first hole injection material and the highest occupied molecular orbital energy level of the hole transport material is less than or equal to 0.5 eV. This avoids excessive differences between the lowest unoccupied molecular orbital energy level of the first hole injection material and the highest occupied molecular orbital energy level of the hole transport material, and can facilitate the injection of the hole into the highest occupied molecular orbital of the hole transport material, and thus improves the charge migration capability.

For example, the absolute value of the difference between the LUMO energy level of the first hole injection material and the HOMO energy level of the hole transport material is defined as: PD1_LUMO-HT_HOMO, where the sign of the difference is not limited, and its absolute value is less than or equal to 0.5 eV.

It should be noted that in the present application, the absolute value of the difference in energy levels can be understood as: making the difference first, and then taking the absolute value.

Optionally, the absolute value of the difference between the lowest unoccupied molecular orbital energy level of the second hole injection material and the highest occupied molecular orbital energy level of the hole transport material is less than or equal to 2 eV, which avoids excessive differences between the lowest unoccupied molecular orbital energy level of the second hole injection material and the highest occupied molecular orbital energy level of the hole transport material, can facilitate charge separation, and thus is conducive to lowering the driving voltage.

In some embodiments, the absolute value of the highest occupied molecular orbital energy level of the hole transport material is less than or equal to 5.2 eV, which is conducive for the P-type charge generation sub-layer 32 to perform the energy level matching with other adjacent film layers.

In some embodiments, the N-type charge generation sub-layer 31 comprises a first electron transport material, and the absolute value of the lowest unoccupied molecular orbital energy level of the N-type charge generation sub-layer 31 is in a range of 1.58 eV to 2 eV, which can facilitate injection of the electron into the lowest unoccupied molecular orbital of the N-type charge generation sub-layer 31, thereby improving the charge migration capability.

In some embodiments, the mass percentage of the hole transport material is in a range of 78% to 96%.

For example, as verified by the inventors, the mass percentage of the hole transport material in a range of 78% to 96% can well adjust the multiple energy levels of the P-type charge generation sub-layer 32 so as to match the energy levels of adjacent film layers, effectively forming multi-stage carrier separation channels and thereby improving the charge transfer rate between the first light-emitting unit 10 and the second light-emitting unit 20. For example, the mass percentage of the hole transport material may be any value of 78%, 80%, 85%, 90%, 93% and 96%. The subsequent experimental data and embodiments list the specific implementations where the mass percentage of the hole transport material is 90% and 88% (the ratio of the PCGL host material), and the analysis results 1 to 4 can show the beneficial effects of the hole transport material when its mass percentage is in a range of 78% to 96%.

In some embodiments, the mass percentage of the first hole injection material is in a range of 2% to 12%.

For example, as verified by the inventors, when the mass percentage of the first hole injection material is in a range of 2% to 12%, which can well adjust the multiple energy levels of the P-type charge generation sub-layer 32 to match the energy levels of the adjacent film layers, effectively forming multi-stage carrier separation channels and thereby improving the charge transfer rate between the first light-emitting unit 10 and the second light-emitting unit 20. For example, the mass percentage of the first hole injection material may be any value of 2%, 5%, 7%, 8%, 10% and 12%. The subsequent experimental data and embodiments list the specific implementations where the mass percentage of the first hole injection material is 6% and 4% (the ratio of PCGL doping material 1), and the analysis results 1 to 4 can show the beneficial effects of the first hole injection material when its mass percentage is in a range of 2% to 12%.

In some embodiments, the mass percentage of the second hole injection material is in a range of 1% to 10%.

For example, as verified by the inventors, when the mass percentage of the second hole injection material is in a range of 1% to 10%, which can well adjust the multiple energy levels of the P-type charge generation sub-layer 32 to well match the energy levels of the adjacent film layers, effectively forming multi-stage carrier separation channels and thereby improving the charge transfer rate between the first light-emitting unit 10 and the second light-emitting unit 20. For example, the mass percentage of the second hole injection material may be any value of 1%, 2%, 5%, 7%, 8% and 10%. The subsequent experimental data and embodiments list the specific implementations where the mass percentage of the second hole injection material is 6% and 4% (the ratio of PCGL doping material 2), and the analysis results 1 to 4 can show the beneficial effects of the second hole injection material when its mass percentage is in a range of 1% to 10%.

In some embodiments, the thickness of the P-type charge generation sub-layer 32 is in a range of 50 angstroms to 200 angstroms.

For example, as verified by the inventors, when the thickness of the P-type charge generation sub-layer 32 is in a range of 50 angstroms to 200 angstroms, the thickness of the P-type charge generation sub-layer 32 is appropriate to avoid that the thickness of the P-type charge generation sub-layer 32 is too small to effectively adjust the energy levels, and to avoid that the thickness of the P-type charge generation sub-layer 32 is excessively large, thereby avoiding excessive resistance of the P-type charge generation sub-layer 32. For example, the thickness of the P-type charge generation sub-layer 32 may be any value of 50 angstroms, 80 angstroms, 100 angstroms, 120 angstroms, 150 angstroms, 180 angstroms and 200 angstroms. The subsequent experimental data and embodiments list the specific implementations where the thickness of the P-type charge generation sub-layer 32 is 100 angstroms, 110 angstroms, 114 angstroms and 120 angstroms (thickness of PCGL layer), and the analysis results 1 to 4 can show the beneficial effects of the P-type charge generation sub-layer 32 when its thickness is in a range of 50 angstroms to 200 angstroms.

For example, in some embodiments, as verified in the subsequent experimental data and embodiments by the inventors, if the following conditions are all satisfied: the mass percentage of the hole transport material is in a range of 78% to 96%; the mass percentage of the first hole injection material is in a range of 2% to 12%; the mass percentage of the second hole injection material is in a range of 1% to 10%; and the thickness of the P-type charge generation sub-layer 32 is in a range of 50 angstroms to 200 angstroms, then the multiple energy levels of the P-type charge generation sub-layer 32 can best match the energy levels of the adjacent film layers, better improving the charge transfer rate between the first light-emitting unit 10 and the second light-emitting unit 20, and better reducing the charge lateral transfer capability of the charge generation layer 30. Hence, a lower driving voltage is required to drive the light-emitting device 100, thereby better enhancing the luminous efficiency of the light-emitting device 100.

In some embodiments, the second hole injection material comprises at least one of the following materials A1 to A39:

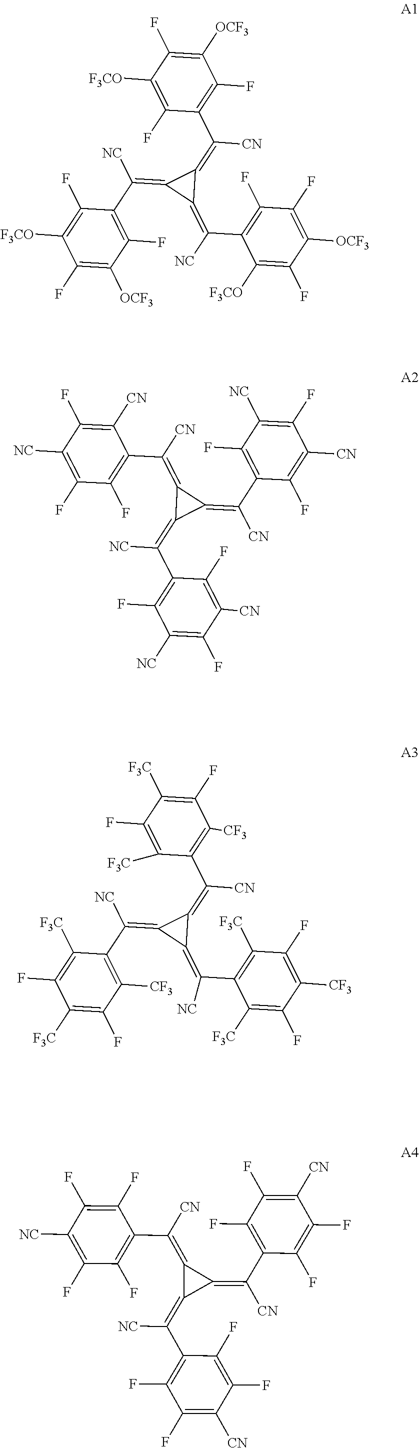

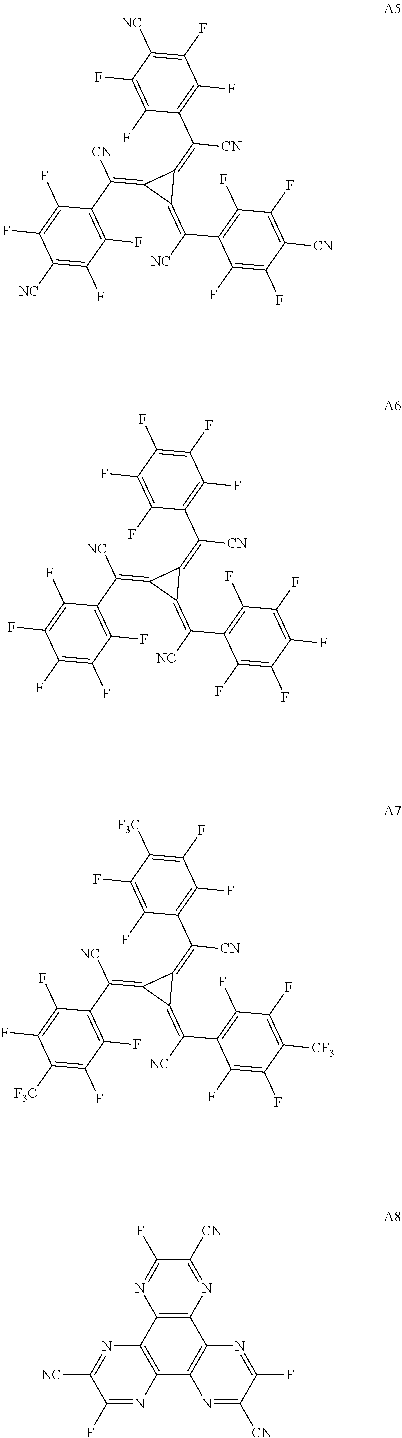 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(=C1C(=C(C#N)c2c(F)c(F)c(F)c(F)c2F)C1=C(C#N)c1c(F)c(F)c(F)c(F)c1F)c1c(F)c(F)c(F)c(F)c1F ; N#CC(=C1C(=C(C#N)c2c(F)c(F)c(C(F)(F)F)c(F)c2F)C1=C(C#N)c1c(F)c(F)c(C(F)(F)F)c(F)c1F)c1c(F)c(F)c(C(F)(F)F)c(F)c1F ; N#Cc1nc2c(nc1F)c1nc(C#N)c(F)nc1c1nc(C#N)c(F)nc21]

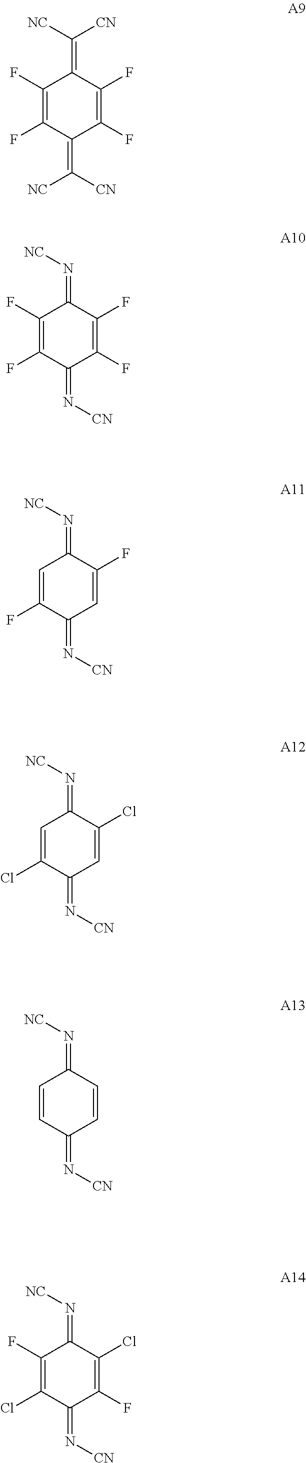 [SMILES: N#CC(C#N)=c1c(F)c(F)c(=C(C#N)C#N)c(F)c1F ; N#CN=C1C(F)=C(F)C(=NC#N)C(F)=C1F ; N#C/N=C1C=C(F)/C(=N/C#N)C=C\1F ; N#C/N=C1C=C(Cl)/C(=N/C#N)C=C\1Cl ; N#CN=C1C=CC(=NC#N)C=C1 ; N#C/N=C1C(F)=C(Cl)/C(=N/C#N)C(F)=C\1Cl]

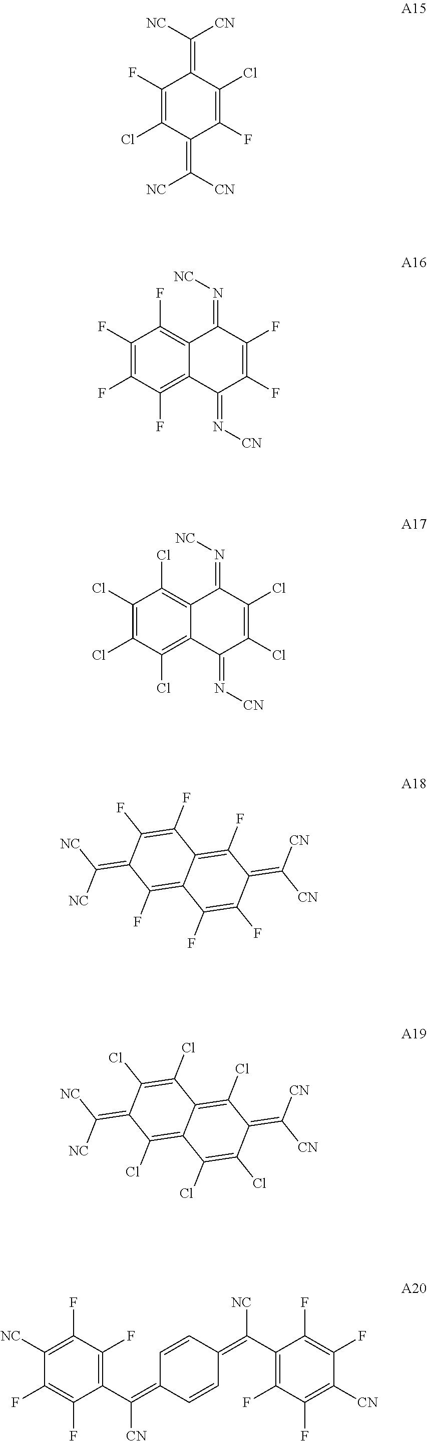 [SMILES: N#CC(C#N)=c1c(F)c(Cl)c(=C(C#N)C#N)c(F)c1Cl ; N#C/N=C1C(F)=C(F)/C(=N/C#N)c2c(F)c(F)c(F)c(F)c2\1 ; N#C/N=C1C(Cl)=C(Cl)/C(=N/C#N)c2c(Cl)c(Cl)c(Cl)c(Cl)c2\1 ; N#CC(C#N)=c1c(F)c(F)c2c(F)c(=C(C#N)C#N)c(F)c(F)c2c1F ; N#CC(C#N)=c1c(Cl)c(Cl)c2c(Cl)c(=C(C#N)C#N)c(Cl)c(Cl)c2c1Cl ; N#CC(c1c(F)c(F)c(C#N)c(F)c1F)=c1ccc(=C(C#N)c2c(F)c(F)c(C#N)c(F)c2F)cc1]

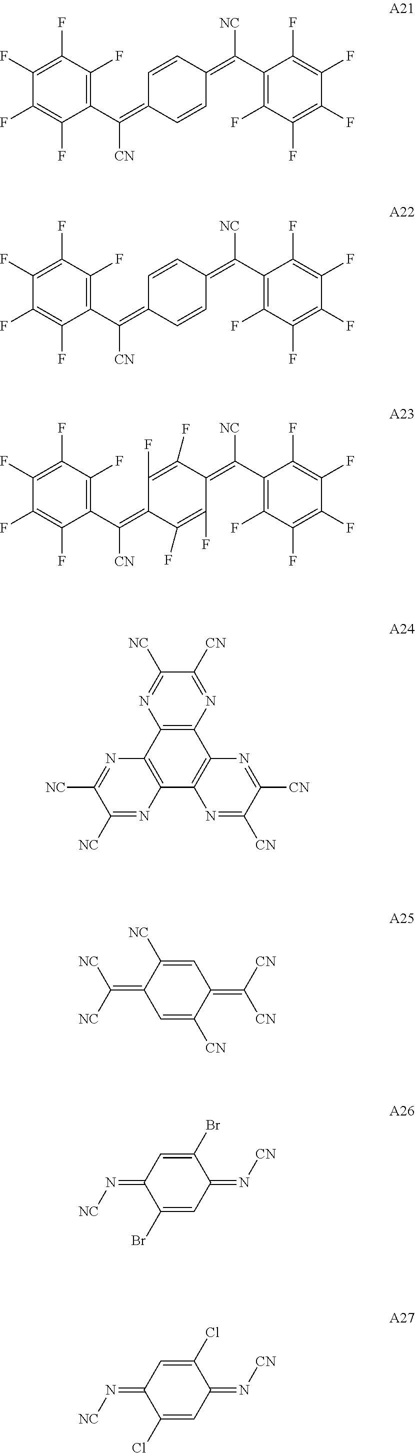

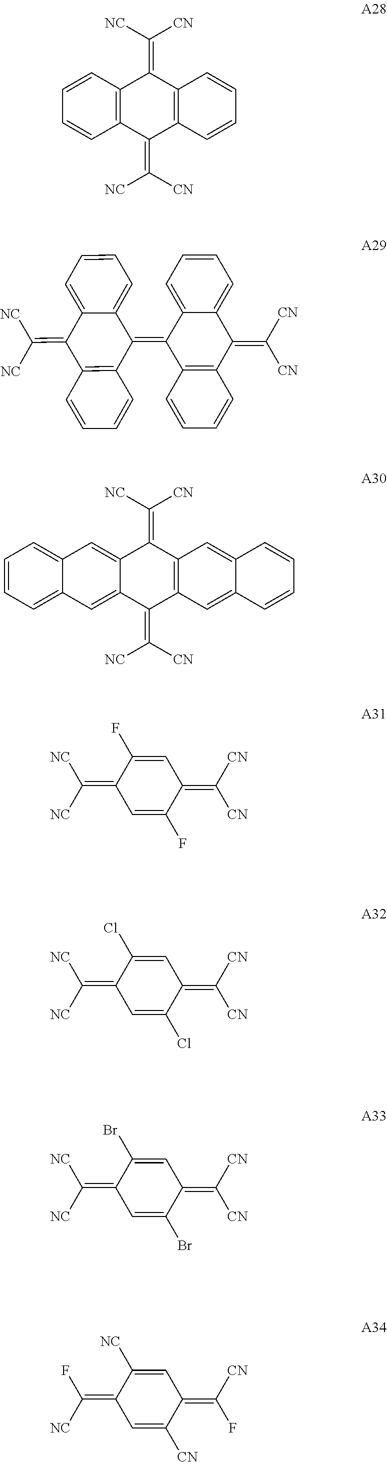

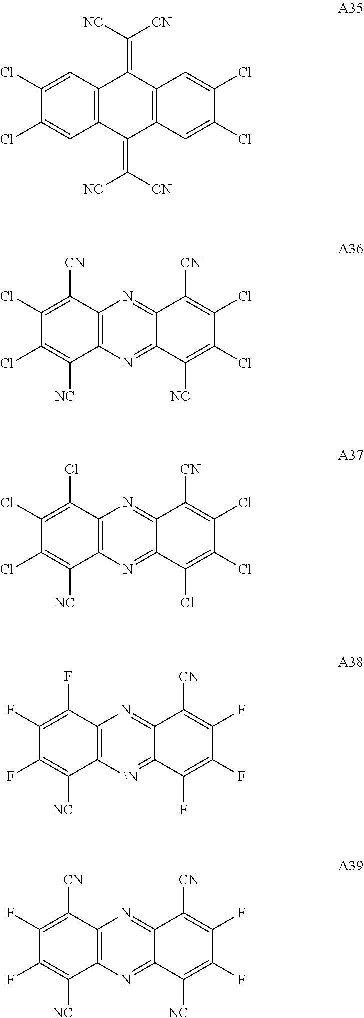

For example, although some materials and molecular formulas of the second hole injection material are listed herein as examples, which are not limited to the materials and molecular formulas of the second hole injection material listed here as examples.

In some embodiments, the first hole injection material comprises a compound represented by the following Formula 1:

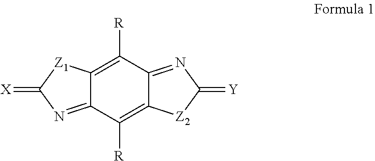

where X and Y are each independently selected from CR″R′″, NR′, O, S or Se;
where Z1 and Z2 are each independently selected from O, S or Se;
R, R′, R″ and R′″ are each independently selected from the group consisting of hydrogen, deuterium, halogen, nitroso, nitro, acyl, carbonyl, carboxyl, ester, cyano, isocyano, SCN, OCN, SF5, boryl, sulfinyl, sulfonyl, phosphinoxy, substituted or unsubstituted alkyl containing 1 to 20 carbon atoms, substituted or unsubstituted cycloalkyl containing 3 to 20 ring carbon atoms, substituted or unsubstituted heteroalkyl containing 1 to 20 carbon atoms, substituted or unsubstituted aralkyl containing 7 to 30 carbon atoms, substituted or unsubstituted alkoxy containing 1 to 20 carbon atoms, substituted or unsubstituted aryloxy containing 6 to 30 carbon atoms, substituted or unsubstituted alkenyl containing 2 to 20 carbon atoms, substituted or unsubstituted alkynyl containing 2 to 20 carbon atoms, substituted or unsubstituted aryl with 6 to 30 carbon atoms, substituted or unsubstituted heteroaryl containing 3 to 30 carbon atoms, substituted or unsubstituted alkylsilyl containing 3 to 20 carbon atoms, substituted or unsubstituted arylsilyl containing 6 to 20 carbon atoms, and combinations thereof;
where each R may be the same or different, and at least one of R, R′, R″ and R′″ is a group having at least one electron-withdrawing group;
where the adjacent substituents may be optionally connected to form a ring.

For example, in some embodiments, in the compound of Formula 1, X and Y are each independently selected from CR″R′″ or NR′, and R′, R″ and R″″ are groups having at least one electron-withdrawing group. Optionally, R, R′, R″, and R′″ are groups having at least one electron-withdrawing group.

For example, in some embodiments, in the compound of Formula 1, X and Y are each independently selected from O, S or Se, and at least one of R is a group having at least one electron-withdrawing group. Optionally, R is a group having at least one electron-withdrawing group.

For example, in some embodiments, in the compound of Formula 1, the Hammett constant of the electron-withdrawing group is greater than or equal to 0.05, optionally, it is greater than or equal to 0.3, optionally, it is greater than or equal to 0.5.

For example, in some embodiments, in the compound of Formula 1, the electron-withdrawing group is selected from the group consisting of halogen, nitroso, nitro, acyl, carbonyl, carboxyl, ester, cyano, isocyano, SCN, OCN, SF5, boryl, sulfinyl, sulfonyl, phosphinoxy, nitrogen-containing heteroaryl, and any of the following groups substituted with one or more of halogen, nitroso, nitro, acyl, carbonyl, carboxyl, ester, cyano, isocyano, SCN, OCN, SF5, boryl, sulfinyl, sulfonyl, phosphinoxy, nitrogen-containing heteroaryl:alkyl containing 1 to 20 carbon atoms, cycloalkyl containing 3 to 20 ring carbon atoms, heteroalkyl containing 1 to 20 carbon atoms, aralkyl containing 7 to 30 carbon atoms, alkoxy containing 1 to 20 carbon atoms, aryloxy containing 6 to 30 carbon atoms, alkenyl containing 2 to 20 carbon atoms, alkynyl containing 2 to 20 carbon atoms, aryl containing 6 to 30 carbon atoms, heteroaryl containing 3 to 30 carbon atoms, alkylsilyl containing 3 to 20 carbon atoms, arylsilyl containing 6 to 20 carbon atoms, and combinations thereof. Optionally, the electron-withdrawing group is selected from the group consisting of F, CF3, OCF3, SF5, SO2CF3, cyano, isocyano, SCN, OCN, pyrimidinyl, triazinyl, and combinations thereof.

In some embodiments, the first hole injection material comprises at least one of the following B1 to B30:

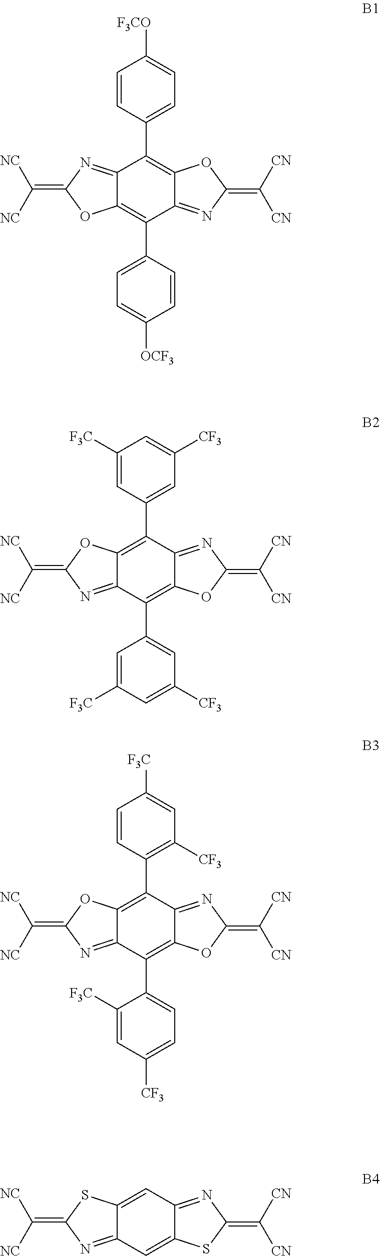 [SMILES: N#CC(C#N)=c1nc2c(-c3ccc(OC(F)(F)F)cc3)c3oc(=C(C#N)C#N)nc3c(-c3ccc(OC(F)(F)F)cc3)c2o1 ; N#CC(C#N)=c1nc2c(-c3cc(C(F)(F)F)cc(C(F)(F)F)c3)c3oc(=C(C#N)C#N)nc3c(-c3cc(C(F)(F)F)cc(C(F)(F)F)c3)c2o1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; N#CC(C#N)=c1nc2cc3sc(=C(C#N)C#N)nc3cc2s1]

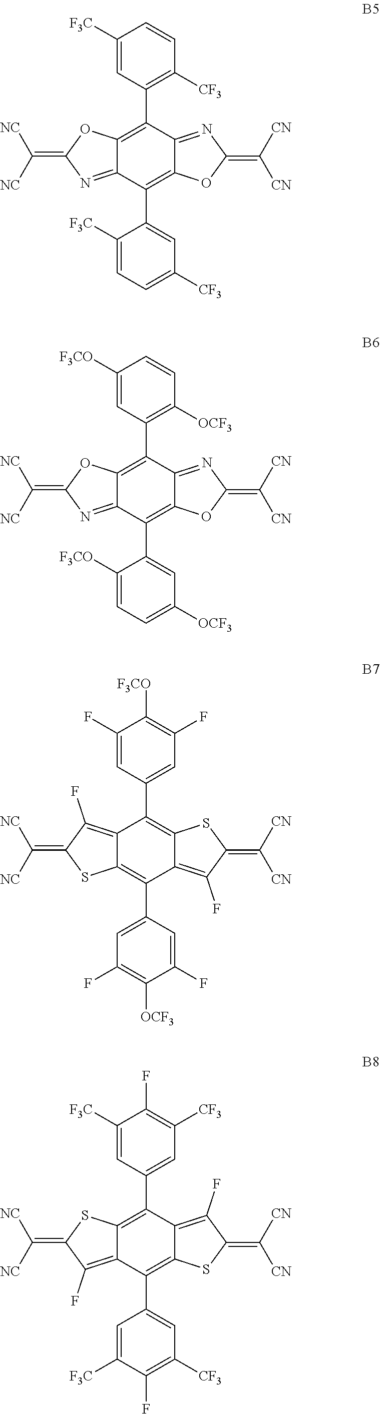 [SMILES: N#CC(C#N)=c1nc2c(-c3cc(C(F)(F)F)ccc3C(F)(F)F)c3oc(=C(C#N)C#N)nc3c(-c3cc(C(F)(F)F)ccc3C(F)(F)F)c2o1 ; N#CC(C#N)=c1nc2c(-c3cc(OC(F)(F)F)ccc3OC(F)(F)F)c3oc(=C(C#N)C#N)nc3c(-c3cc(OC(F)(F)F)ccc3OC(F)(F)F)c2o1 ; N#CC(C#N)=c1sc2c(-c3cc(F)c(OC(F)(F)F)c(F)c3)c3c(F)c(=C(C#N)C#N)sc3c(-c3cc(F)c(OC(F)(F)F)c(F)c3)c2c1F ; N#CC(C#N)=c1sc2c(-c3cc(C(F)(F)F)c(F)c(C(F)(F)F)c3)c3c(F)c(=C(C#N)C#N)sc3c(-c3cc(C(F)(F)F)c(F)c(C(F)(F)F)c3)c2c1F]

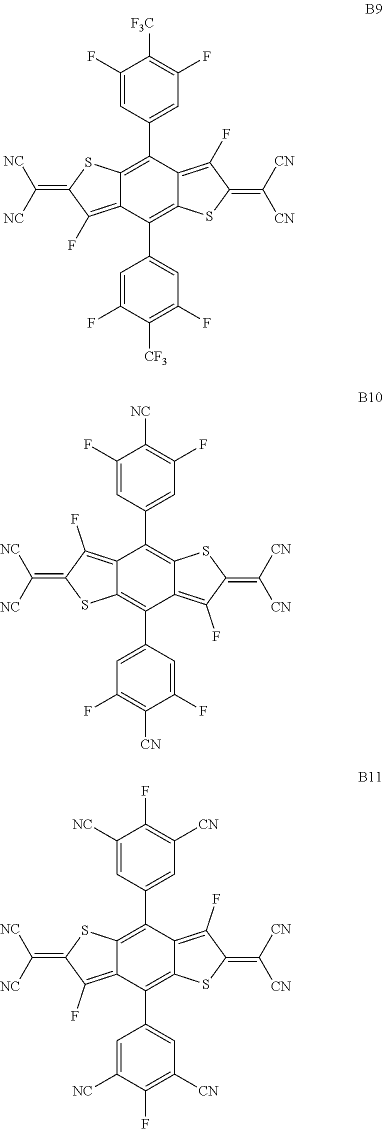

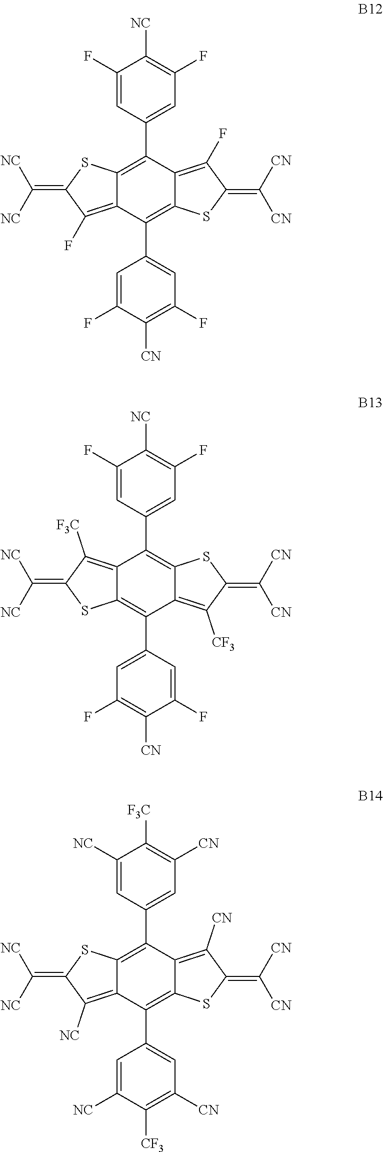 [SMILES: N#CC(C#N)=c1sc2c(-c3cc(F)c(C#N)c(F)c3)c3c(F)c(=C(C#N)C#N)sc3c(-c3cc(F)c(C#N)c(F)c3)c2c1F ; N#CC(C#N)=c1sc2c(-c3cc(F)c(C#N)c(F)c3)c3c(C(F)(F)F)c(=C(C#N)C#N)sc3c(-c3cc(F)c(C#N)c(F)c3)c2c1C(F)(F)F ; N#CC(C#N)=c1sc2c(-c3cc(C#N)c(C(F)(F)F)c(C#N)c3)c3c(C#N)c(=C(C#N)C#N)sc3c(-c3cc(C#N)c(C(F)(F)F)c(C#N)c3)c2c1C#N]

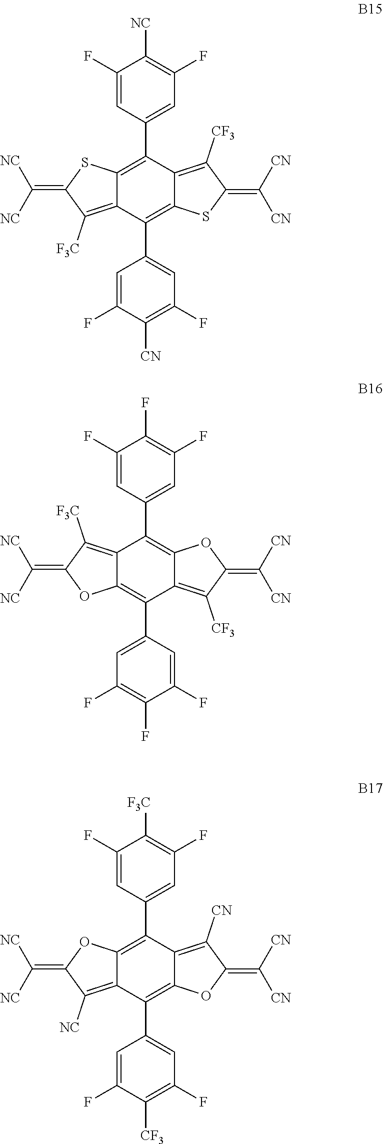

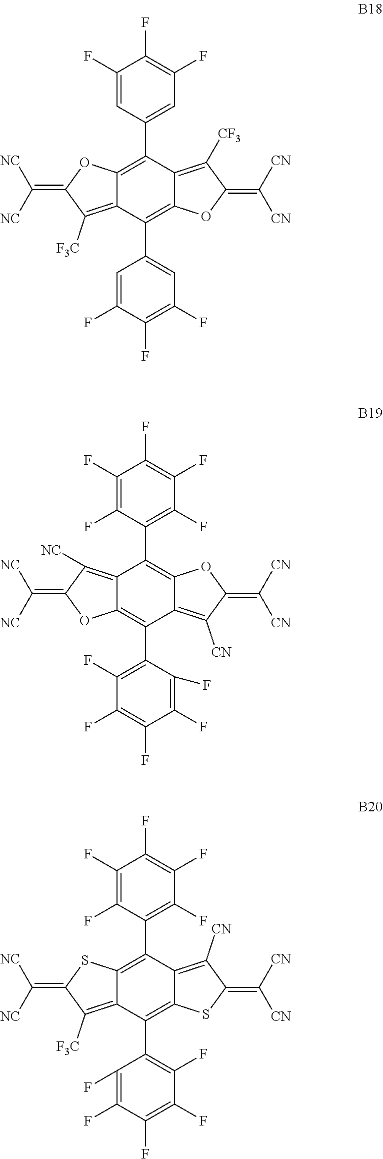 [SMILES: N#CC(C#N)=c1oc2c(-c3cc(F)c(F)c(F)c3)c3c(C(F)(F)F)c(=C(C#N)C#N)oc3c(-c3cc(F)c(F)c(F)c3)c2c1C(F)(F)F ; N#CC(C#N)=c1oc2c(-c3c(F)c(F)c(F)c(F)c3F)c3c(C#N)c(=C(C#N)C#N)oc3c(-c3c(F)c(F)c(F)c(F)c3F)c2c1C#N ; N#CC(C#N)=c1sc2c(-c3c(F)c(F)c(F)c(F)c3F)c3c(C(F)(F)F)c(=C(C#N)C#N)sc3c(-c3c(F)c(F)c(F)c(F)c3F)c2c1C#N]

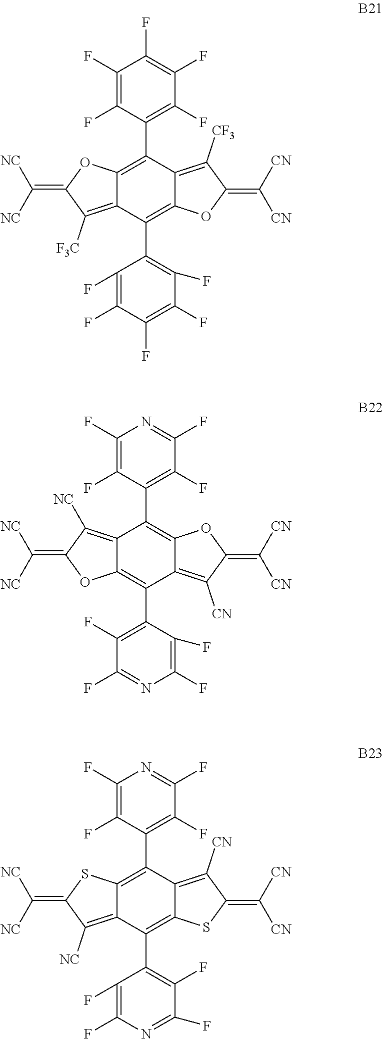 [SMILES: N#CC(C#N)=c1oc2c(-c3c(F)c(F)c(F)c(F)c3F)c3c(C(F)(F)F)c(=C(C#N)C#N)oc3c(-c3c(F)c(F)c(F)c(F)c3F)c2c1C(F)(F)F ; N#CC(C#N)=c1oc2c(-c3c(F)c(F)nc(F)c3F)c3c(C#N)c(=C(C#N)C#N)oc3c(-c3c(F)c(F)nc(F)c3F)c2c1C#N ; N#CC(C#N)=c1sc2c(-c3c(F)c(F)nc(F)c3F)c3c(C#N)c(=C(C#N)C#N)sc3c(-c3c(F)c(F)nc(F)c3F)c2c1C#N]

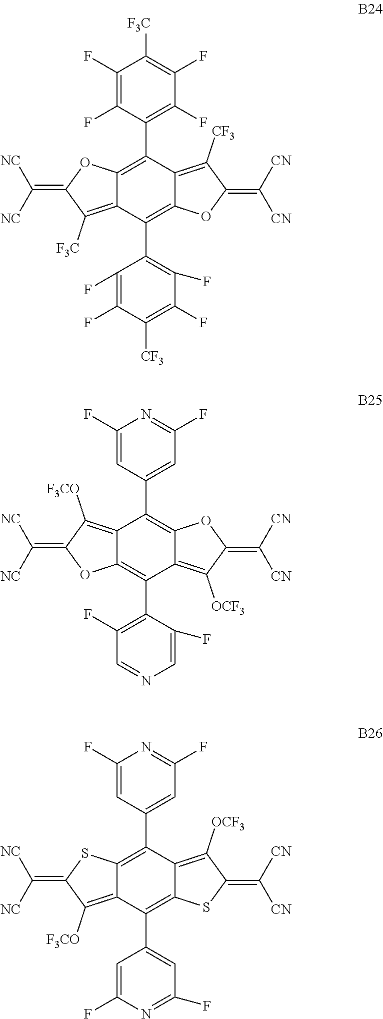 [SMILES: N#CC(C#N)=c1oc2c(-c3c(F)c(F)c(C(F)(F)F)c(F)c3F)c3c(C(F)(F)F)c(=C(C#N)C#N)oc3c(-c3c(F)c(F)c(C(F)(F)F)c(F)c3F)c2c1C(F)(F)F ; N#CC(C#N)=c1oc2c(-c3c(F)cncc3F)c3c(OC(F)(F)F)c(=C(C#N)C#N)oc3c(-c3cc(F)nc(F)c3)c2c1OC(F)(F)F ; N#CC(C#N)=c1sc2c(-c3cc(F)nc(F)c3)c3c(OC(F)(F)F)c(=C(C#N)C#N)sc3c(-c3cc(F)nc(F)c3)c2c1OC(F)(F)F]

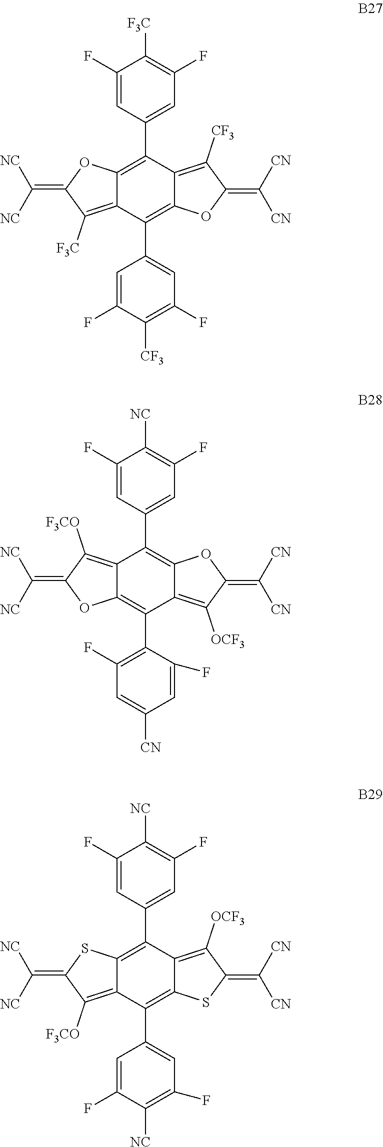 [SMILES: N#CC(C#N)=c1oc2c(-c3cc(F)c(C(F)(F)F)c(F)c3)c3c(C(F)(F)F)c(=C(C#N)C#N)oc3c(-c3cc(F)c(C(F)(F)F)c(F)c3)c2c1C(F)(F)F ; N#CC(C#N)=c1oc2c(-c3c(F)cc(C#N)cc3F)c3c(OC(F)(F)F)c(=C(C#N)C#N)oc3c(-c3cc(F)c(C#N)c(F)c3)c2c1OC(F)(F)F ; N#CC(C#N)=c1sc2c(-c3cc(F)c(C#N)c(F)c3)c3c(OC(F)(F)F)c(=C(C#N)C#N)sc3c(-c3cc(F)c(C#N)c(F)c3)c2c1OC(F)(F)F]

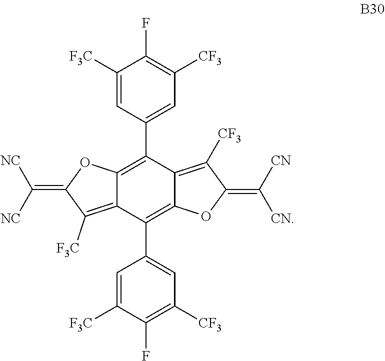 [SMILES: N#CC(C#N)=c1oc2c(-c3cc(C(F)(F)F)c(F)c(C(F)(F)F)c3)c3c(C(F)(F)F)c(=C(C#N)C#N)oc3c(-c3cc(C(F)(F)F)c(F)c(C(F)(F)F)c3)c2c1C(F)(F)F]

For example, although some materials and molecular formulas of the first hole injection material are listed here as examples, the materials of the first hole injection material are not limited to the materials and molecular formulas of the first hole injection material listed herein as examples.

In some embodiments, the hole transport material included in the P-type charge generation sub-layer 32 comprises at least one of the following C1 to C55:

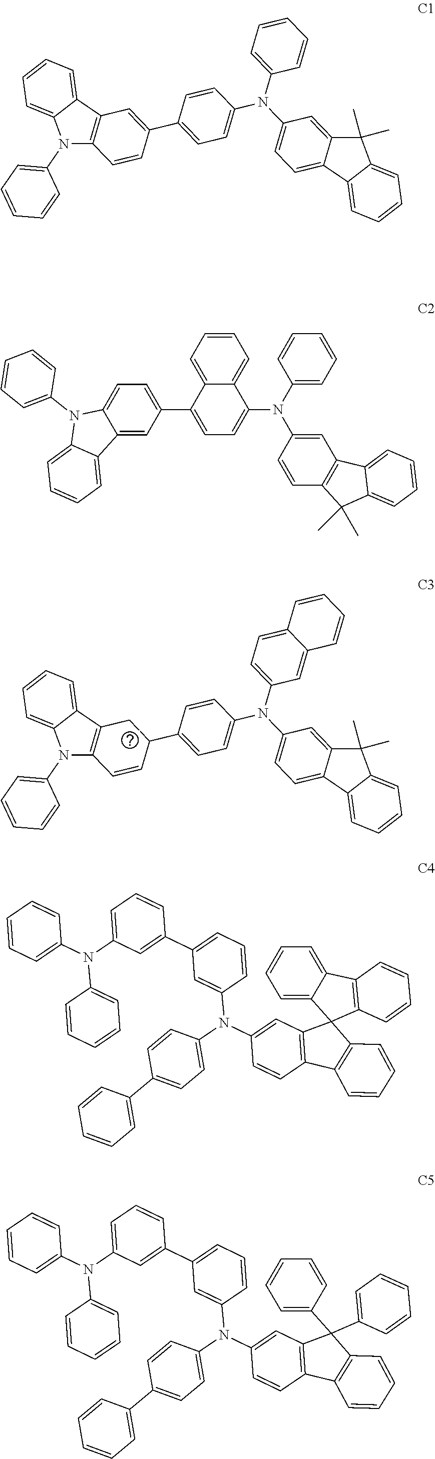 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2cc(N(c3ccccc3)c3ccc(-c4ccc5c(c4)c4ccccc4n5-c4ccccc4)c4ccccc34)ccc21 ; CC1(C)c2ccccc2-c2ccc(N(c3ccc(C4C=Cc5c(c6ccccc6n5-c5ccccc5)C4)cc3)c3ccc4ccccc4c3)cc21 ; c1ccc(-c2ccc(N(c3cccc(-c4cccc(N(c5ccccc5)c5ccccc5)c4)c3)c3ccc4c(c3)C3(c5ccccc5-c5ccccc53)c3ccccc3-4)cc2)cc1 ; c1ccc(-c2ccc(N(c3cccc(-c4cccc(N(c5ccccc5)c5ccccc5)c4)c3)c3ccc4c(c3)C(c3ccccc3)(c3ccccc3)c3ccccc3-4)cc2)cc1]

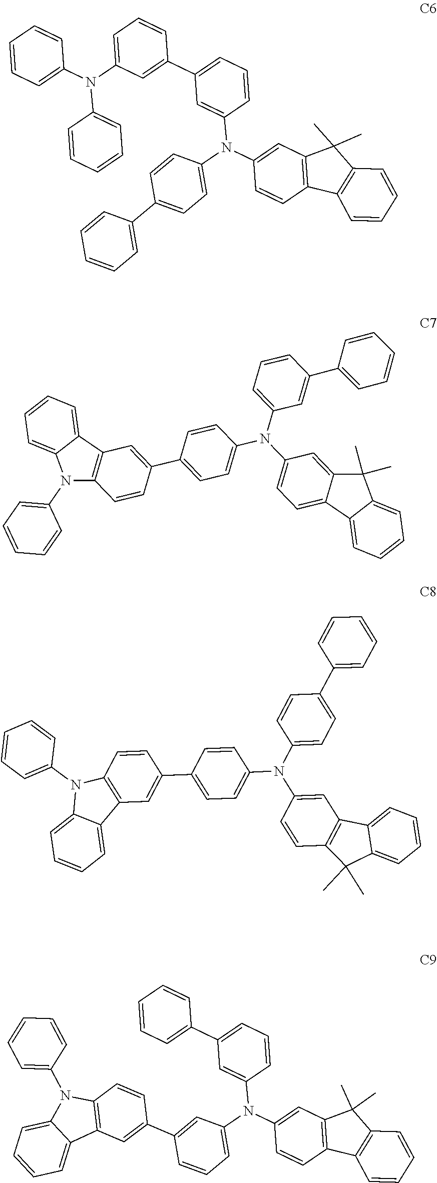 [SMILES: CC1(C)c2ccccc2-c2ccc(N(c3ccc(-c4ccccc4)cc3)c3cccc(-c4cccc(N(c5ccccc5)c5ccccc5)c4)c3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2cc(N(c3ccc(-c4ccccc4)cc3)c3ccc(-c4ccc5c(c4)c4ccccc4n5-c4ccccc4)cc3)ccc21 ; CC1(C)c2ccccc2-c2ccc(N(c3cccc(-c4ccccc4)c3)c3cccc(-c4ccc5c(c4)c4ccccc4n5-c4ccccc4)c3)cc21]

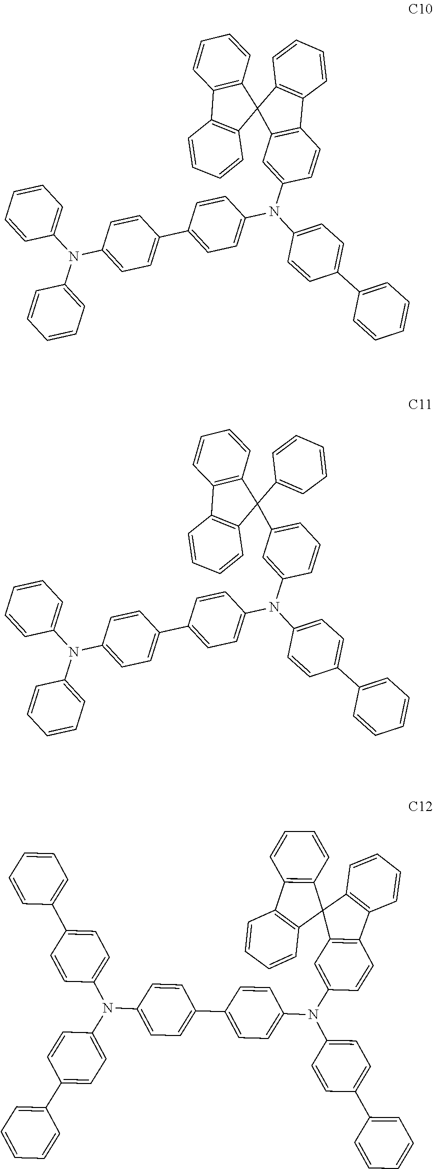 [SMILES: c1ccc(-c2ccc(N(c3ccc(-c4ccc(N(c5ccccc5)c5ccccc5)cc4)cc3)c3ccc4c(c3)C3(c5ccccc5-c5ccccc53)c3ccccc3-4)cc2)cc1 ; c1ccc(-c2ccc(N(c3ccc(-c4ccc(N(c5ccccc5)c5ccccc5)cc4)cc3)c3cccc(C4(c5ccccc5)c5ccccc5-c5ccccc54)c3)cc2)cc1 ; c1ccc(-c2ccc(N(c3ccc(-c4ccccc4)cc3)c3ccc(-c4ccc(N(c5ccc(-c6ccccc6)cc5)c5ccc6c(c5)C5(c7ccccc7-c7ccccc75)c5ccccc5-6)cc4)cc3)cc2)cc1]

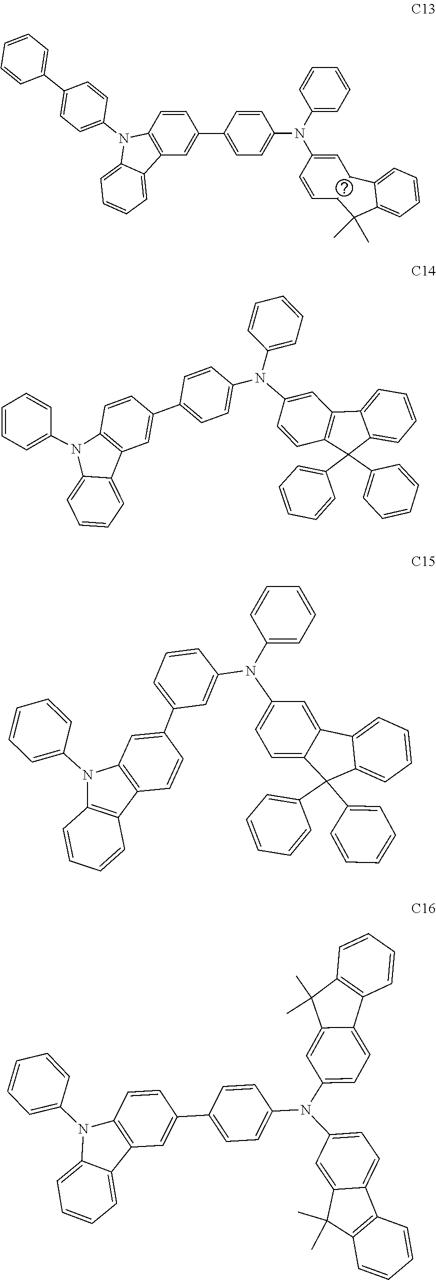 [SMILES: CC1(C)c2ccccc2C2C=C(N(c3ccccc3)c3ccc(-c4ccc5c(c4)c4ccccc4n5-c4ccc(-c5ccccc5)cc4)cc3)C=CC21 ; c1ccc(N(c2ccc(-c3ccc4c(c3)c3ccccc3n4-c3ccccc3)cc2)c2ccc3c(c2)-c2ccccc2C3(c2ccccc2)c2ccccc2)cc1 ; c1ccc(N(c2cccc(-c3ccc4c5ccccc5n(-c5ccccc5)c4c3)c2)c2ccc3c(c2)-c2ccccc2C3(c2ccccc2)c2ccccc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

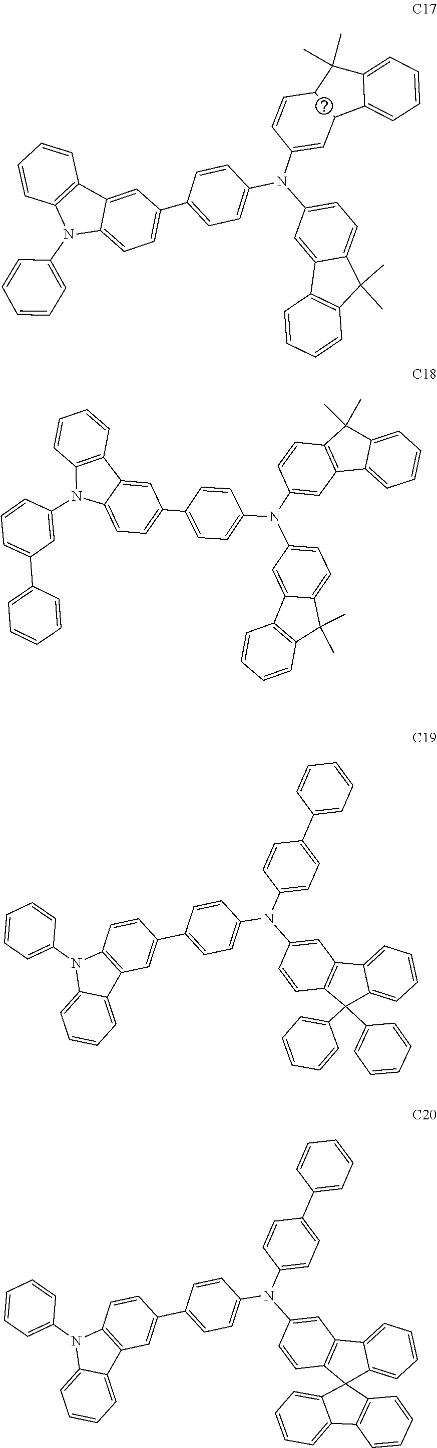 [SMILES: CC1(C)c2ccccc2-c2cc(N(C3=CC4c5ccccc5C(C)(C)C4C=C3)c3ccc(-c4ccc5c(c4)c4ccccc4n5-c4ccccc4)cc3)ccc21 ; CC1(C)c2ccccc2-c2cc(N(c3ccc(-c4ccc5c(c4)c4ccccc4n5-c4cccc(-c5ccccc5)c4)cc3)c3ccc4c(c3)-c3ccccc3C4(C)C)ccc21 ; c1ccc(-c2ccc(N(c3ccc(-c4ccc5c(c4)c4ccccc4n5-c4ccccc4)cc3)c3ccc4c(c3)-c3ccccc3C4(c3ccccc3)c3ccccc3)cc2)cc1 ; c1ccc(-c2ccc(N(c3ccc(-c4ccc5c(c4)c4ccccc4n5-c4ccccc4)cc3)c3ccc4c(c3)-c3ccccc3C43c4ccccc4-c4ccccc43)cc2)cc1]

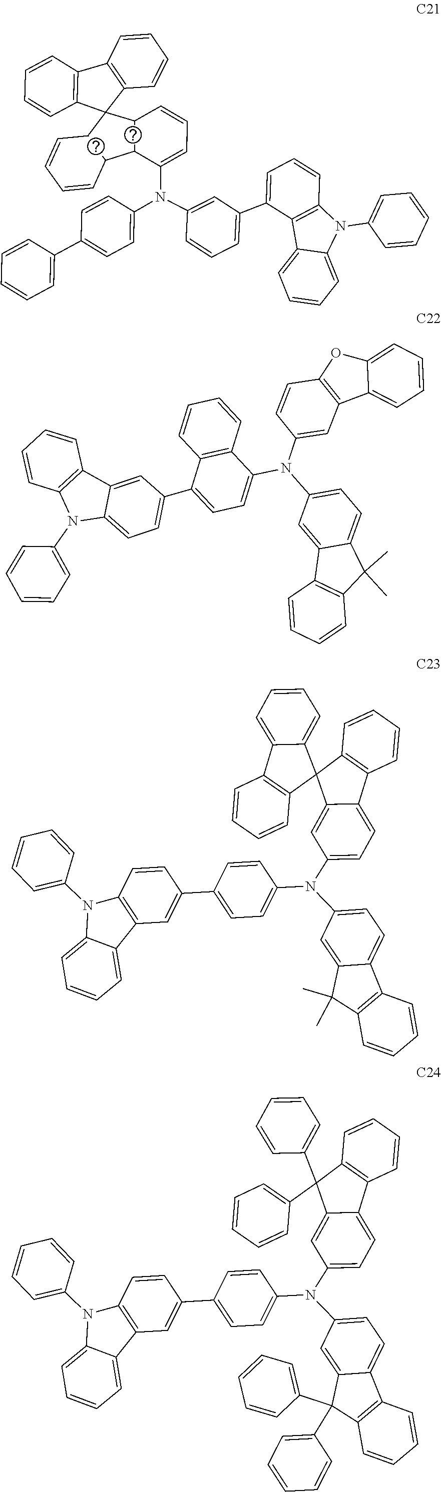 [SMILES: C1=CC2C3C(N(c4ccc(-c5ccccc5)cc4)c4cccc(-c5cccc6c5c5ccccc5n6-c5ccccc5)c4)=CC=CC3C3(c4ccccc4-c4ccccc43)C2C=C1 ; CC1(C)c2ccccc2-c2cc(N(c3ccc4oc5ccccc5c4c3)c3ccc(-c4ccc5c(c4)c4ccccc4n5-c4ccccc4)c4ccccc34)ccc21 ; CC1(C)c2ccccc2-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc21 ; c1ccc(-n2c3ccccc3c3cc(-c4ccc(N(c5ccc6c(c5)C(c5ccccc5)(c5ccccc5)c5ccccc5-6)c5ccc6c(c5)C(c5ccccc5)(c5ccccc5)c5ccccc5-6)cc4)ccc32)cc1]

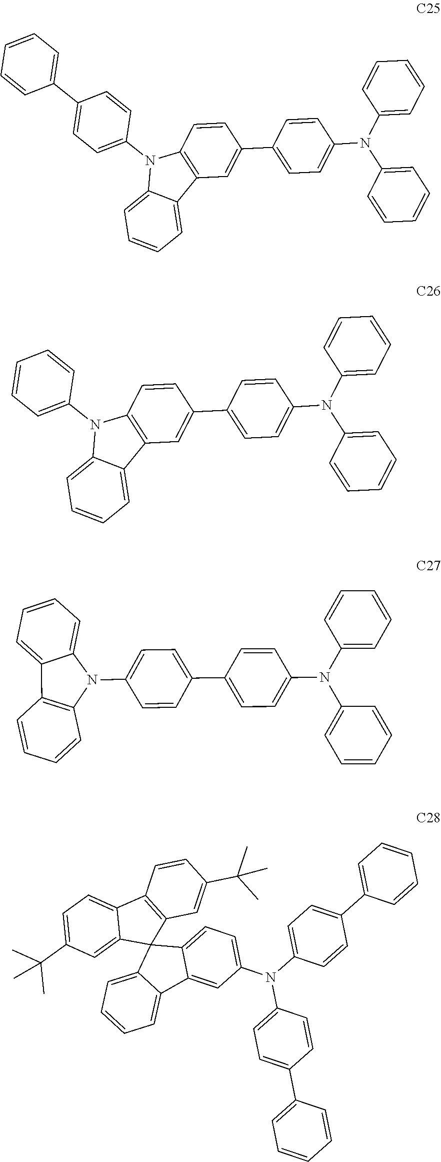 [SMILES: c1ccc(-c2ccc(-n3c4ccccc4c4cc(-c5ccc(N(c6ccccc6)c6ccccc6)cc5)ccc43)cc2)cc1 ; c1ccc(N(c2ccccc2)c2ccc(-c3ccc4c(c3)c3ccccc3n4-c3ccccc3)cc2)cc1 ; c1ccc(N(c2ccccc2)c2ccc(-c3ccc(-n4c5ccccc5c5ccccc54)cc3)cc2)cc1 ; CC(C)(C)c1ccc2c(c1)C1(c3ccccc3-c3cc(N(c4ccc(-c5ccccc5)cc4)c4ccc(-c5ccccc5)cc4)ccc31)c1cc(C(C)(C)C)ccc1-2]

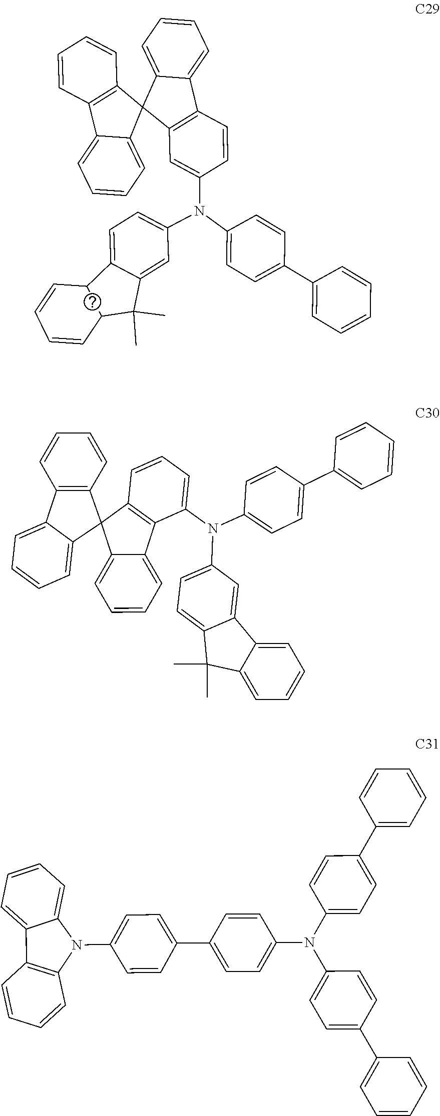 [SMILES: CC1(C)c2cc(N(c3ccc(-c4ccccc4)cc3)c3ccc4c(c3)C3(c5ccccc5-c5ccccc53)c3ccccc3-4)ccc2C2C=CC=CC21 ; CC1(C)c2ccccc2-c2cc(N(c3ccc(-c4ccccc4)cc3)c3cccc4c3-c3ccccc3C43c4ccccc4-c4ccccc43)ccc21 ; c1ccc(-c2ccc(N(c3ccc(-c4ccccc4)cc3)c3ccc(-c4ccc(-n5c6ccccc6c6ccccc65)cc4)cc3)cc2)cc1]

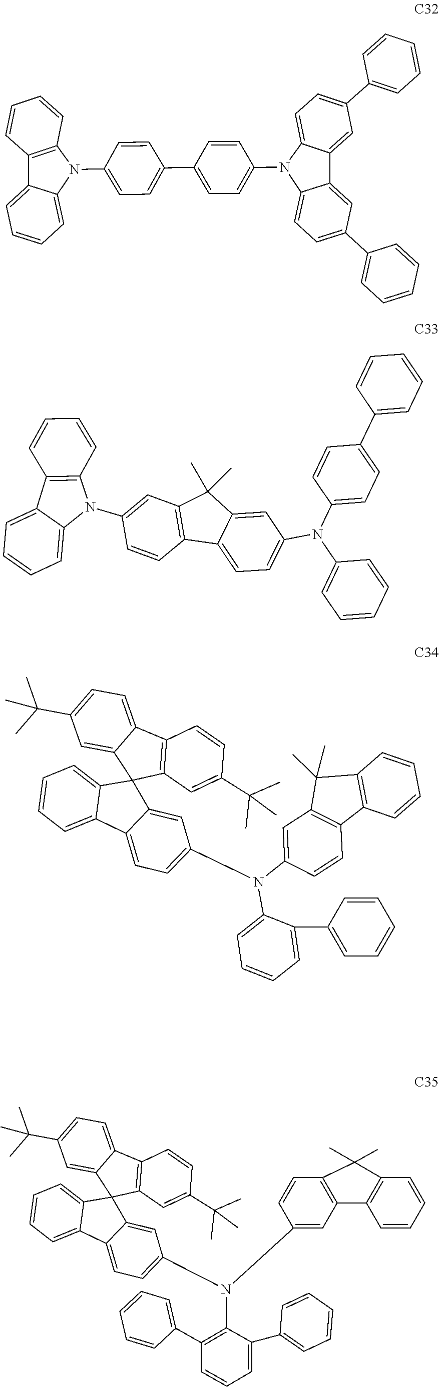 [SMILES: c1ccc(-c2ccc3c(c2)c2cc(-c4ccccc4)ccc2n3-c2ccc(-c3ccc(-n4c5ccccc5c5ccccc54)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC(C)(C)c1ccc2c(c1)C1(c3ccccc3-c3ccc(N(c4ccc5c(c4)-c4ccccc4C5(C)C)c4c(-c5ccccc5)cccc4-c4ccccc4)cc31)c1cc(C(C)(C)C)ccc1-2]

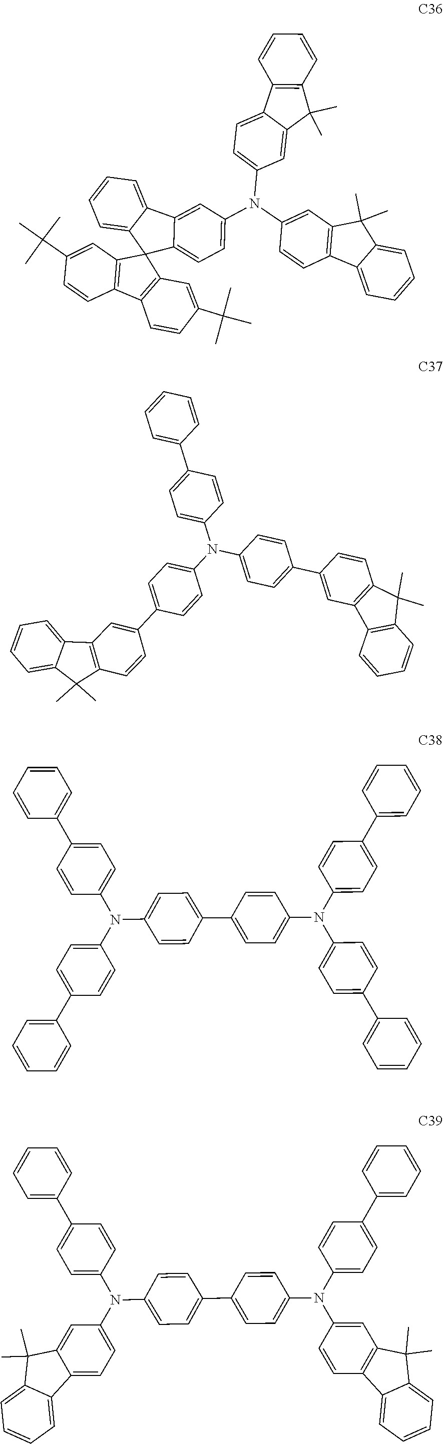 [SMILES: CC(C)(C)c1ccc2c(c1)C1(c3ccccc3-c3cc(N(c4ccc5c(c4)C(C)(C)c4ccccc4-5)c4ccc5c(c4)C(C)(C)c4ccccc4-5)ccc31)c1cc(C(C)(C)C)ccc1-2 ; CC1(C)c2ccccc2-c2cc(-c3ccc(N(c4ccc(-c5ccccc5)cc4)c4ccc(-c5ccc6c(c5)-c5ccccc5C6(C)C)cc4)cc3)ccc21 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; CC1(C)c2ccccc2-c2ccc(N(c3ccc(-c4ccccc4)cc3)c3ccc(-c4ccc(N(c5ccc(-c6ccccc6)cc5)c5ccc6c(c5)C(C)(C)c5ccccc5-6)cc4)cc3)cc21]

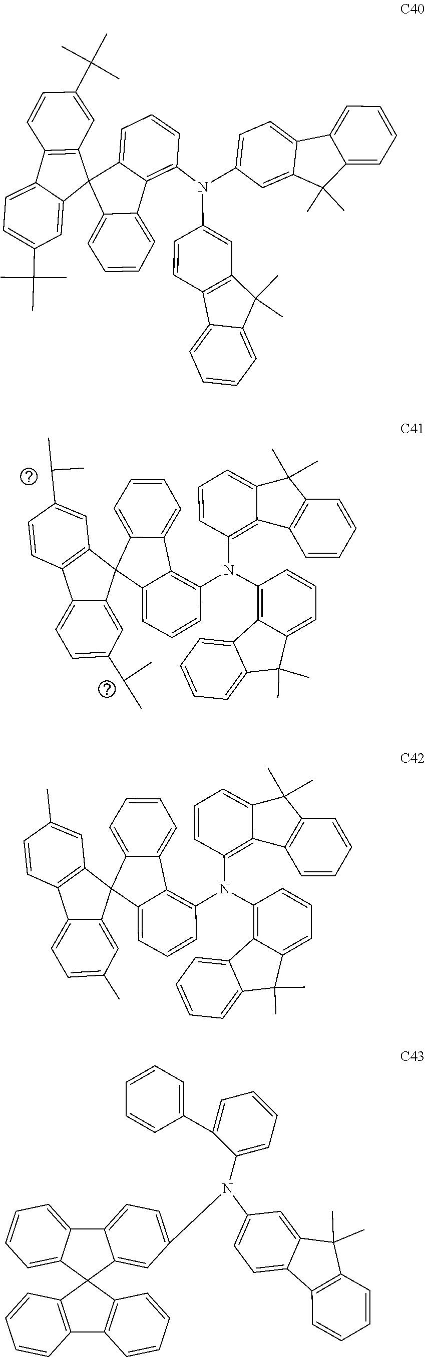 [SMILES: CC(C)(C)c1ccc2c(c1)C1(c3cc(C(C)(C)C)ccc3-2)c2ccccc2-c2c(N(c3ccc4c(c3)C(C)(C)c3ccccc3-4)c3ccc4c(c3)C(C)(C)c3ccccc3-4)cccc21 ; CC(C)c1ccc2c(c1)C1(c3cc(C(C)C)ccc3-2)c2ccccc2-c2c(N(c3cccc4c3-c3ccccc3C4(C)C)c3cccc4c3-c3ccccc3C4(C)C)cccc21 ; Cc1ccc2c(c1)C1(c3cc(C)ccc3-2)c2ccccc2-c2c(N(c3cccc4c3-c3ccccc3C4(C)C)c3cccc4c3-c3ccccc3C4(C)C)cccc21 ; CC1(C)c2ccccc2-c2ccc(N(c3ccc4c(c3)C3(c5ccccc5-c5ccccc53)c3ccccc3-4)c3ccccc3-c3ccccc3)cc21]

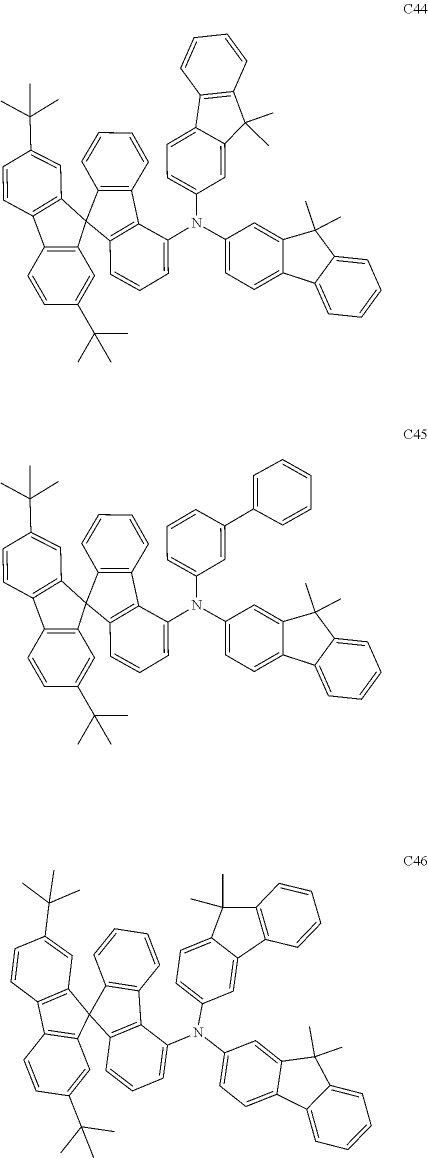 [SMILES: CC(C)(C)c1ccc2c(c1)C1(c3cc(C(C)(C)C)ccc3-2)c2ccccc2-c2c(N(c3ccc4c(c3)C(C)(C)c3ccccc3-4)c3ccc4c(c3)C(C)(C)c3ccccc3-4)cccc21 ; CC(C)(C)c1ccc2c(c1)C1(c3cc(C(C)(C)C)ccc3-2)c2ccccc2-c2c(N(c3cccc(-c4ccccc4)c3)c3ccc4c(c3)C(C)(C)c3ccccc3-4)cccc21 ; CC(C)(C)c1ccc2c(c1)C1(c3cc(C(C)(C)C)ccc3-2)c2ccccc2-c2c(N(c3ccc4c(c3)-c3ccccc3C4(C)C)c3ccc4c(c3)C(C)(C)c3ccccc3-4)cccc21]

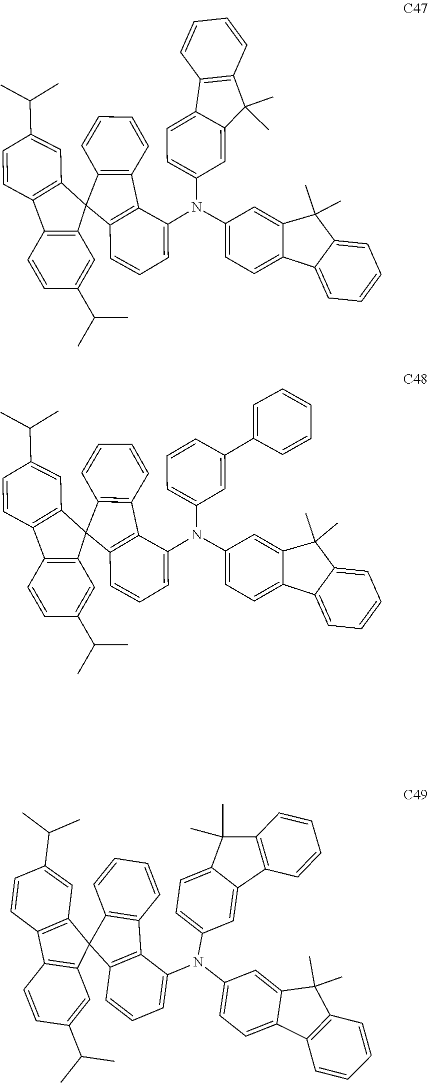 [SMILES: CC(C)c1ccc2c(c1)C1(c3cc(C(C)C)ccc3-2)c2ccccc2-c2c(N(c3ccc4c(c3)C(C)(C)c3ccccc3-4)c3ccc4c(c3)C(C)(C)c3ccccc3-4)cccc21 ; CC(C)c1ccc2c(c1)C1(c3cc(C(C)C)ccc3-2)c2ccccc2-c2c(N(c3cccc(-c4ccccc4)c3)c3ccc4c(c3)C(C)(C)c3ccccc3-4)cccc21 ; CC(C)c1ccc2c(c1)C1(c3cc(C(C)C)ccc3-2)c2ccccc2-c2c(N(c3ccc4c(c3)-c3ccccc3C4(C)C)c3ccc4c(c3)C(C)(C)c3ccccc3-4)cccc21]

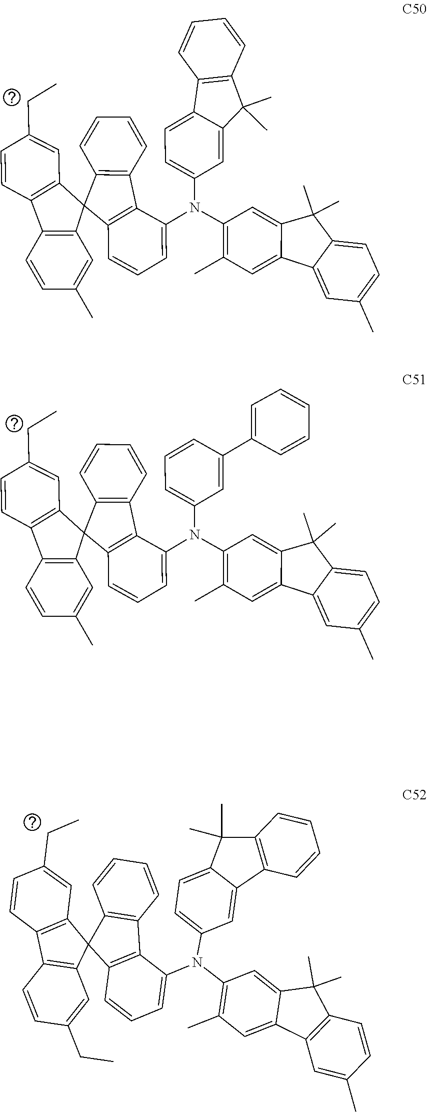 [SMILES: CCc1ccc2c(c1)C1(c3cc(C)ccc3-2)c2ccccc2-c2c(N(c3ccc4c(c3)C(C)(C)c3ccccc3-4)c3cc4c(cc3C)-c3cc(C)ccc3C4(C)C)cccc21 ; CCc1ccc2c(c1)C1(c3cc(C)ccc3-2)c2ccccc2-c2c(N(c3cccc(-c4ccccc4)c3)c3cc4c(cc3C)-c3cc(C)ccc3C4(C)C)cccc21 ; CCc1ccc2c(c1)C1(c3cc(CC)ccc3-2)c2ccccc2-c2c(N(c3ccc4c(c3)-c3ccccc3C4(C)C)c3cc4c(cc3C)-c3cc(C)ccc3C4(C)C)cccc21]

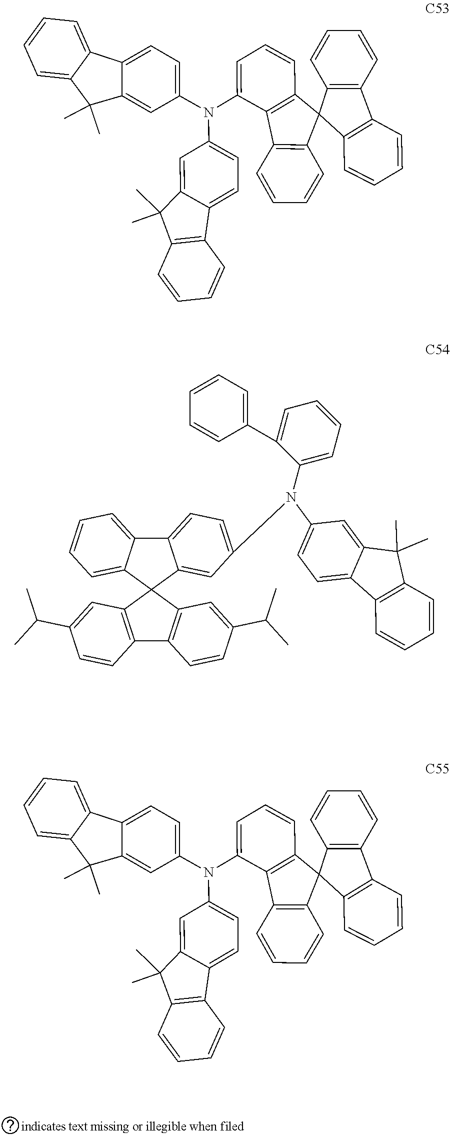 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21 ; CC(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)C)ccc1-2 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21]

In some embodiments, as shown in FIG. 3, the charge generation layer 30 further comprises a first intermediate sub-layer 33 disposed between the P-type charge generation sub-layer 32 and the N-type charge generation sub-layer 31. The first intermediate sub-layer 33 comprises a third hole injection material, and the absolute value of the lowest unoccupied molecular orbital energy level of the third hole injection material is less than that of the first hole injection material.

For example, firstly, the first intermediate sub-layer 33 is located between the P-type charge generation sub-layer 32 and the N-type charge generation sub-layer 31, which reduces the energy gap between the P-type charge generation sub-layer 32 and the N-type charge generation sub-layer 31, enabling electron injection transfer and thereby lowering the driving voltage of the light-emitting device 100. Secondly, the thickness of the first intermediate sub-layer 33 is relatively thin, which increases the lateral resistance of the light-emitting device (the resistance in the direction perpendicular to the thickness of the light-emitting device, or the resistance in the direction parallel to the plane where the anode is located), thereby reducing the lateral flow of charges in the light-emitting device and decreasing the lateral leakage current of the light-emitting device. The subsequent experimental data and the analysis result 2 of the embodiments demonstrate that the arrangement of the first intermediate sub-layer 33 enables the light-emitting device to have a lower operating voltage and a higher current efficiency, and achieves a smaller lateral leakage current, thereby further enhancing the overall performance of the device.

For example, in some embodiments, the first intermediate sub-layer 33 is the neat third hole injection material.

In some embodiments, as shown in FIG. 3, the third hole injection material and the second hole injection material are the same material, which reduces the variety of choices for the material, and thus lowers production costs and production difficulties.

For example, in some embodiments, the first intermediate sub-layer 33 is the neat second hole injection material.

In some embodiments, as shown in FIG. 3, the thickness of the first intermediate sub-layer 33 is less than or equal to 10 angstroms.

For example, as verified by the inventors, the thickness of the first intermediate sub-layer 33 is less than or equal to 10 angstroms as shown in FIG. 3, which can avoid that the thickness of the first intermediate sub-layer 33 is excessively large, thereby avoiding excessive resistance of the charge generation layer 30.

In some embodiments, as shown in FIG. 4 or FIG. 5, the N-type charge generation sub-layer 31 comprises a first electron transport material and an N-type dopant. The charge generation layer 30 further comprises a second intermediate sub-layer 34 disposed between the P-type charge generation sub-layer 32 and the N-type charge generation sub-layer 31. The second intermediate sub-layer 34 is disposed in contact with the N-type charge generation sub-layer 31, and the material of the second intermediate sub-layer 34 is the second electron transport material.

For example, as shown in FIG. 4, the charge generation layer 30 of the light-emitting device 100 comprises the N-type charge generation sub-layer 31, the second intermediate sub-layer 34, and the P-type charge generation sub-layer 32 stacked in sequence on the anode 101.

For example, as shown in FIG. 4, the second intermediate sub-layer 34 introduced between the P-type charge generation sub-layer 32 and the N-type charge generation sub-layer 31 can prevent the diffusion of metal in the N-type dopant of the N-type charge generation sub-layer 31, for example, to slow down the diffusion of ytterbium (Yb) from the N-type charge generation sub-layer into the P-type charge generation sub-layer. Also, it can prevent the N-type dopant in the N-type charge generation sub-layer 31 from directly contacting and reacting with the P-type dopant of the P-type charge generation sub-layer 32 to damage the interface, and reduces a drift voltage of the device (the voltage difference before and after the lifetime of the light-emitting device is tested when the lifetime of the light-emitting device is tested at a certain temperature and current density), and thus enhances the stability of the light-emitting device. The subsequent experimental data and the analysis result 3 of the embodiments also demonstrate that addition of the second intermediate sub-layer 34 enables the light-emitting device to have a lower operating voltage and higher current efficiency, and achieves a smaller drift voltage, thereby further enhancing the stability of the device.

For example, as shown in FIG. 5, the charge generation layer 30 of the light-emitting device 100 comprises the N-type charge generation sub-layer 31, the second intermediate sub-layer 34, the first intermediate sub-layer 33, and the P-type charge generation sub-layer 32 stacked in sequence on the anode 101.

For example, as shown in FIG. 5, the second intermediate sub-layer 34 introduced between the first intermediate sub-layer 33 and the N-type charge generation sub-layer 31 can prevent the diffusion of metal in the N-type dopant of the N-type charge generation sub-layer 31, for example, to slow down the diffusion of ytterbium (Yb) from the N-type charge generation sub-layer into the P-type charge generation sub-layer. Also, it can prevent the N-type dopant in the N-type charge generation sub-layer 31 from directly contacting and reacting with the P-type dopant in the P-type charge generation sub-layer 32 to damage the interface, and reduces the drift voltage of the device (the voltage difference before and after the lifetime of the light-emitting device is tested when the lifetime of the light-emitting device is tested at a certain temperature and current density), and thus enhances the stability of the light-emitting device. The subsequent experimental data and the analysis result 4 of the embodiments demonstrate that addition of the second intermediate sub-layer 34 enables the light-emitting device to have a lower operating voltage and higher current efficiency, and achieves a smaller drift voltage and smaller lateral leakage current, which not only lowers the power consumption of the device and reduces the lateral leakage, but also enhances the stability of the device, thereby significantly optimizing the overall performance of the device.

For example, in some embodiments, the material of the second intermediate sub-layer 34 is the neat second electron transport material.

In some embodiments, as shown in FIG. 4 or FIG. 5, the second electron transport material and the first electron transport material are the same material, which can reduce the selected types of the material, thereby lowering production costs and production difficulties.

In some embodiments, the thickness of the second intermediate sub-layer 34 is in a range of 5 angstroms to 20 angstroms.

For example, as verified by the inventors, when the thickness of the second intermediate sub-layer 34 is in a range of 5 angstroms to 20 angstroms, the thickness of the second intermediate sub-layer 34 is appropriate, which can avoid that the thickness of the second intermediate sub-layer 34 is too small to effectively adjust the energy level, avoid that the thickness of the second intermediate sub-layer 34 is too small to prevent the diffusion of the metal in the N-type dopant of the N-type charge generation sub-layer 31, and avoid that the thickness of the second intermediate sub-layer 34 is excessively large, thereby avoiding the excessive resistance of the charge generation layer 30. For example, the thickness of the second intermediate sub-layer 34 may be any value of 5 angstroms, 8 angstroms, 10 angstroms, 12 angstroms, 15 angstroms, 18 angstroms and 20 angstroms.

It should be noted that, as shown in FIGS. 2 to 5, the first light-emitting unit 10 and the second light-emitting unit 20 may each comprises an emission layer (EML), and may further comprise other film layers other than the emission layer (EML), for example, one or more of a hole injection layer (HIL), a hole transport layer (HTL), an electron injection layer (EIL), an electron transport layer (ETL), a hole blocking layer (HBL) and an electron blocking layer (EBL).

It should be noted that, as shown in FIGS. 2 to 5, the light-emitting device 100 (tandem OLED device) comprises the following structures in sequence from bottom to top: the anode 101, the hole injection layer 12, the first hole transport layer 13, the first emission layer 14, the first hole blocking layer 15, the first electron transport layer 16, the charge generation layer 30, the second hole transport layer 22, the second emission layer 23, the second hole blocking layer 24, the second electron transport layer 25, the electron injection layer 26, the cathode 102 and a capping layer 41. However, the structures of the first light-emitting unit 10 and the second light-emitting unit 20 are not limited to the examples in FIGS. 2 to 5.

In some embodiments, the capping layer 41 is disposed on the upper surface of the cathode 102 and covers the cathode 102 to reduce the light loss of the device.

In some embodiments, the material of the anode 101 may be selected from metals such as copper, gold, silver, iron, chromium, nickel, manganese, palladium, platinum or their alloys, or metal oxides such as indium oxide, zinc oxide, indium tin oxide (ITO), indium zinc oxide (IZO), etc., or conductive polymers such as polyaniline, polypyrrole, poly (3-methylthiophene), etc. In addition, the material of the anode 101 may also be selected from materials and combinations thereof other than the materials listed above, which are conducive to hole injection and includes known materials suitable for the anode 101.

In some embodiments, the material of the cathode 102 may be selected from metals such as aluminum, magnesium, silver, calcium, indium, tin, titanium, etc., or their alloys, or multilayer metal materials such as LiF/Al, LiO2/Al, BaF2/Al, etc. In addition to the materials listed above, the material of the cathode 102 may be the materials and combinations thereof that are conducive to electron injection and includes known materials suitable for the cathode 102.

In some embodiments, the hole injection layer and the hole transport layer may each independently comprise, but are not limited to, at least one of 4,4′,4″-tris(3-methylphenylamino) triphenylamine (MTDATA), 4,4′,4″-tris(N,N-diphenylamino)triphenylamine (NATA), 4,4′,4″-tris(N-(naphthalene-1-yl)-N-phenylamino)triphenylamine (IT-NATA), 4,4′,4″-tris(N-(naphthalene-2-yl)-N-phenylamino)triphenylamine (2TNATA), copper phthalocyanine (CuPc), 1,3,5-tris[4-(diphenylamino)phenyl]benzene (TDAPB), 2,2′-dimethyl-N,N′-di-1-naphthyl-N,N′-diphenyl[1,1′-biphenyl]-4,4′-diamine (α-NPD), 4,4′,4″-tris(carbazole-9-yl)triphenylamine (TCTA), 1,3-dicarbazole-9-ylbenzene (mCP), 4,4′-di(9-carbazole)biphenyl (CBP), 3,3′-di(N-carbazole)-1,1′-biphenyl (mCBP), 2,3,6,7,10,11-hexacyano-1,4,5,8,9,12-hexaazatriphenylene (HATCN), 4,4′-cyclohexylbis[N,N-di(4-methylphenyl)aniline (TAPC), N,N′-diphenyl-N,N′-(1-naphthyl)-1,1′-biphenyl-4,4′-diamine (α-NPB), N,N′-di(naphthalene-2-yl)-N,N′-di(phenyl)biphenyl-4,4′-diamine (NPB), poly(3,4-ethylenedioxythiophene)-polystyrene sulfonate (PEDOT:PSS), 2,3,5,6-tetrafluoro-7,7,8,8-tetracyanoquinodimethane (F4TCNQ), N-(biphenyl-4-yl)-9,9-dimethyl-N-(4-(9-phenyl-9H-carbazole-3-yl)phenyl)-9H-fluorene-2-amine polyvinylcarbazole (PVK), 4,4′-bis(N-carbazole)-1,1′-biphenyl (CBP), poly[N,N′-bis(4-butylphenyl)-N,N′-bis(phenyl)-benzidine] (poly-TPD), poly[(9,9-dioctylfluorenyl-2,7-diyl)-co-(4,4′-(N-(4-sec-butylphenyl)diphenylamine))] (TFB), 1,1-bis[4-(N,N′-di(p-tolyl)amino) phenyl) cyclohexane (TAPC), 3,5-di(9H-carbazole-9-yl)-N,N-diphenylaniline (DCDPA), N-(biphenyl-4-yl)-9,9-dimethyl-N-(4-(9-phenyl-9H-carbazole-3-yl)phenyl)-9H-fluorene-2-amine, N-(biphenyl-4-yl)-N-(4-(9-phenyl-9H-carbazole-3-yl)phenyl)biphenyl-4-amine, N-([1,1′-biphenyl]-4-yl)-9,9-dimethyl-N-(4-(9-phenyl-9H-carbazole-3-yl)phenyl)-9H-fluorene-2-amine, N4,N4,N4′,N4′-tetra([1,1′-biphenyl]-4-yl)-[1,1′-biphenyl]-4,4′-diamine)-9-phenyl-3,9-bicarbazole (CCP), and molybdenum trioxide (MoO3).

In some embodiments, the electron injection layer may comprise, but is not limited to, at least one of Yb, Li, Cs, and Cs₂CO₃.

In some embodiments, the emission layers (the first emission layer 14 and the second emission layer 23) comprise host materials and doping materials. The host materials comprise red light host materials, green light host materials, and blue light host materials. The doping materials comprise red light doping materials, green light doping materials, and blue light doping materials. Specifically, the doping materials may be selected from at least one of fluorescent materials, phosphorescent materials, thermally activated delayed fluorescent materials, and aggregation-induced emission materials. Specifically, the host materials may be selected from, but are not limited to, at least one of 2,8-di(diphenylphosphinyl)dibenzothiophene, 4,4′-di(9-carbazole)biphenyl, 3,3′-di(N-carbazolyl)-1,1′-biphenyl, 2,8-bis(diphenylphosphinyl)dibenzofuran, bis(4-(9H-carbazolyl-9-yl)phenyl)diphenylsilane, 9-(4-tert-butylphenyl)-3,6-bis(triphenylsilyl)-9H-carbazole, bis(2-diphenylphosphinyl)diphenyl ether, 1,3-bis[3,5-di(pyridin-3-yl)phenyl]benzene, 4,6-bis(3,5-di(3-pyridyl)phenyl)-2-methylpyrimidine, 9-(3-(9H-carbazolyl-9-yl)phenyl)-9H-carbazole-3-cyano, 9-phenyl-9-[4-(triphenylsilyl)phenyl]-9H-fluorene, 1,3,5-tris(1-phenyl-1H-benzimidazol-2-yl)benzene, diphenyl[4-(triphenylsilyl)phenyl]phosphine oxide, 4,4′,4″-tris(carbazolyl-9-yl)triphenylamine, 2,6-dicarbazole-1,5-pyridine, polyvinylcarbazole and polyfluorene.

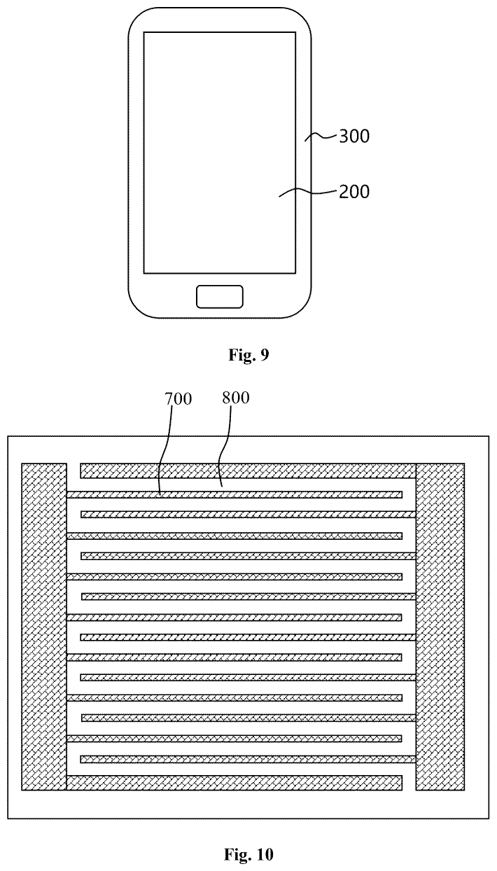

Please refer to FIGS. 8 and 9. FIG. 8 is a schematic diagram of a display panel according to some embodiments of the present application. FIG. 9 is a schematic diagram of a display device according to some embodiments of the present application.

The present application further provides a display panel 200. As shown in FIG. 8, the display panel 200 comprises the light-emitting device 100 described in any of the above embodiments, or the light-emitting device 100 with any of the above features combined.

For example, the display panel 200 also achieves the beneficial effects achieved by the light-emitting device 100 in the above embodiments. The similarities can be understood by referring to the above explanations of the light-emitting device 100, which will not be repeated here.

The present application further provides a display device 300. As shown in FIG. 9, the display device 300 comprises the display panel 200 described in any of the above embodiments, or the display panel 200 with any of the above features combined.

For example, the display device 300 also achieves the beneficial effects achieved by the display panel 200 or the light-emitting device 100 described in the above embodiments. The similarities can be understood by referring to the above explanations of the display panel 200 or the light-emitting device 100, which will not be repeated here.

For example, the display device 300 according to the embodiment of the present application may be a mobile phone as shown in FIG. 9, or any electronic product with a display function, including but not limited to the following categories: televisions, laptops, desktop displays, tablet computers, digital cameras, smart bracelets, smart glasses, vehicle displays, industrial control equipment, medical display screens, touch interactive terminals, etc., which is not specifically limited in the embodiments of the present application.

### Experimental Data and Specific Embodiments

The present application is further described in detail below in conjunction with experimental data and embodiments. These embodiments should not be construed as limiting the scope of protection claimed in the present application.

### Embodiment 1

The light-emitting device 100 (tandem light-emitting device) comprises, in sequence from bottom to top, the anode 101, the hole injection layer 12, the first hole transport layer 13, the first emission layer 14, the first hole blocking layer 15, the first electron transport layer 16, the charge generation layer 30, the second hole transport layer 22, the second emission layer 23, the second hole blocking layer 24, the second electron transport layer 25, the electron injection layer 26, the cathode 102 and the capping layer 41.

This embodiment provides a stacked OLED, the specific preparation steps of which comprise the following steps (1) to (15).
In step (1): a glass substrate was cut to 50 mm×50 mm×0.7 mm in size, subjected to ultrasonic treatments in isopropyl alcohol and as well in deionized water each for 30 minutes, and then exposed to ozone for cleaning for 10 minutes; and afterwards the glass substrate with an ITO anode obtained by magnetron sputtering was loaded on a vacuum deposition device.
In step (2), a hole injection layer was prepared. The compounds C54 and B10 were vacuum evaporated onto the ITO anode layer as the hole injection layer under a vacuum of 2×10-6 Pa to a thickness of 10 nm, where the compound C54 was used as the host material and the compound B10 was used as the doping material, and a mass ratio of C54 to B10 was 97:3.
In step (3), a first hole transport layer was prepared. The compound C54 was vacuum evaporated onto the hole injection layer as the first hole transport layer, where the thickness of the first hole transport layer was 25 nm.
In step (4), a first emission layer was vacuum evaporated onto the first hole transport layer using the organic compound BH-1 as the host material and BD-1 as the doping material, where a mass ratio of BH-1 to BD-1 was 98:2, and the thickness of the first emission layer was 20 nm.
In step (5), a first hole blocking layer was prepared. The compound HB-1 was vacuum evaporated onto the first emission layer as the first hole blocking layer, where the thickness of the first hole blocking layer was 5 nm.
In step (6), a first electron transport layer was prepared. The compounds ET-1 and LiQ were vacuum evaporated onto the first hole blocking layer as the first electron transport layer, where a mass ratio of ET-1 to LiQ was 1:1, and the thickness of the first electron transport layer was 10 nm.
In step (7), an N-type charge generation layer was prepared. The compounds NCGL-1 and Yb were vacuum evaporated onto the first electron transport layer as the N-type charge generation layer, where a mass ratio of NCGL-1 to Yb was 97:3 and the thickness of the N-type charge generation layer was 12 nm.
In step (8), a P-type charge generation layer was prepared. The compounds C54, B10 and A5 were vacuum evaporated onto the N-type charge generation layer as the P-type charge generation layer, where the compound C54 was used as the host material and the compounds B10 and A5 were used as the doping materials, a mass ratio of C54 to B10 to A5 was 90:6:4, and the thickness of the P-type charge generation layer was 12 nm.
In step (9), a second hole transport layer was prepared. The compound C54 was vacuum evaporated onto the P-type charge generation layer as the second hole transport layer, where the thickness of the second hole transport layer was 45 nm.
In step (10), a second emission layer was prepared by vacuum evaporating onto the second hole transport layer the compound BH-1 as the host material and the compound BD-1 as the doping material, where a mass ratio of BH-1 to BD-1 was 98:2, and the thickness of the second emission layer was 20 nm.
In step (11), a second hole blocking layer was prepared. The compound HB-1 was vacuum evaporated onto the second emission layer as the second hole blocking layer, where the thickness of the second hole blocking layer was 5 nm.
In step (12), a second electron transport layer was prepared. The compounds ET-1 and LiQ were vacuum evaporated onto the second hole blocking layer as the second electron transport layer, where a mass ratio of ET-1 to LiQ was 1:1 and the thickness of the second electron transport layer was 30 nm.
In step (13), an electron injection layer was prepared. Yb was vacuum evaporated onto the second electron transport layer as the electron injection layer, where the thickness of the electron injection layer was 1 nm.
In step (14), a cathode was prepared. The magnesium-silver electrode was vacuum evaporated onto the electron injection layer as the cathode, where a mass ratio of Mg to Ag is 1:9 and the thickness of the cathode was 12 nm.
In step (15), a covering layer (capping layer 41) was prepared. The compound CPL-1 was vacuum evaporated onto the cathode as the covering layer, and the tandem OLED device was obtained, where the thickness of the covering layer was 60 nm.

### Embodiments 2 to 7

The difference from Embodiment 1 is that the type or ratio of the host material or doping material used in the P-type charge generation layer in the step (8) is adjusted. The specific differences are shown in Table 1.

### Embodiments 8 to 12

The difference from Embodiment 1 is that after the step (7) is completed, a thin layer of PCGL doping material 2 (A5 or A7) is evaporated to a thickness of 10 angstroms or 6 angstroms, and then the type or ratio of the host material or doping material used in the P-type charge generation layer (PCGL layer) in the step (8) is adjusted. The total thickness of the P-type charge generation layer and the thin layer is controlled to be 120 angstroms in the whole process. The specific differences are shown in Table 1.

### Embodiments 13 to 14

The difference from Embodiment 1 is that after the step (7) is completed, a thin layer of NCGL-1 material is evaporated to a thickness of 10 angstroms, and then the type or ratio of the host material or doping material used in the P-type charge generation layer (PCGL layer) in the step (8) is adjusted. The total thickness of the P-type charge generation layer and the thin layer is controlled to be 120 angstroms in the whole process. The specific differences are shown in Table 1.

### Embodiments 15 to 16

The difference from Embodiment 1 is that after the step (7) is completed, a thin layer of NCGL-1 material is evaporated to a thickness of 10 angstroms, and then a thin layer of PCGL doping material 2 (A5) is evaporated onto the thin layer of NCGL-1 material to a thickness of 10 angstroms, and then the type of the host material used in the P-type charge generation layer (PCGL layer) in the step (8) is adjusted. The total thickness of the P-type charge generation layer and the two thin layers is controlled to be 120 angstroms in the whole process. The specific differences are shown in Table 1.

### Comparative Example 1

The difference from Embodiment 1 is that the PCGL layer in the step (8) is adjusted, that is, compounds C54 and B10 are vacuum evaporated as the P-type charge generation layer, with C54 used as the host material and B10 as the doping material at a mass ratio of 94:6, where the thickness of the PCGL layer is 120 angstroms. The specific differences are shown in Table 1.

### Comparative Example 2

The difference from Embodiment 1 is that the PCGL layer in the step (8) is adjusted, that is, the compounds C54 and B10 are vacuum evaporated as the P-type charge generation layer, where compound C54 is used as the host material, compound B10 is used as the doping material, a mass ratio of the compounds is 90:10, and the thickness of the PCGL layer is 120 angstroms. The specific differences are shown in Table 1.

### Comparative Example 3

The difference from Embodiment 1 is that after the step (7) is completed, NCGL-1 material is evaporated to a thickness of 10 angstroms, and then the PCGL layer in the step (8) is adjusted, that is, the compounds C54 and B10 are vacuum evaporated as the P-type charge generation layer, where compound C54 is used as the host material and compound B10 is used as the doping material, a mass ratio of the compounds is 90:10, and the thickness of the PCGL layer is 110 angstroms. The specific differences are shown in Table 1.

The compound structures used in the tandem OLED devices of the above embodiments or comparative examples are as follows:

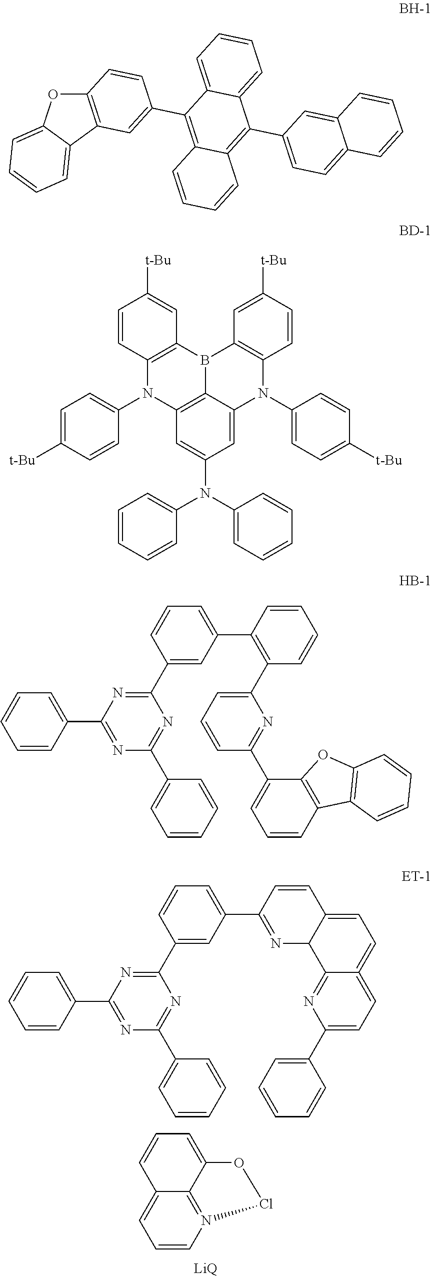

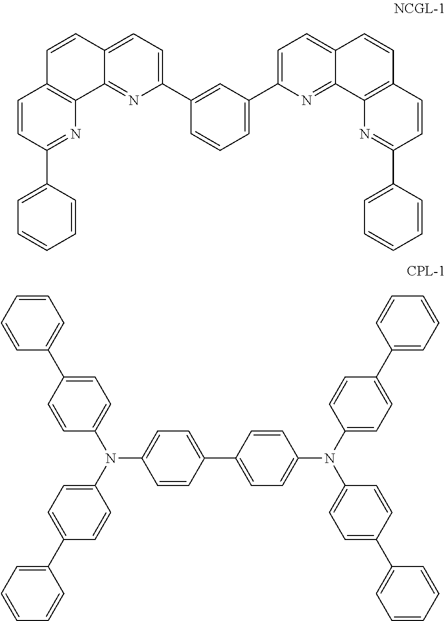 [SMILES: c1ccc(-c2ccc3ccc4ccc(-c5cccc(-c6ccc7ccc8ccc(-c9ccccc9)nc8c7n6)c5)nc4c3n2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

TABLE 1
Structures of charge generation layer of each embodiment and each comparative example

| | Device structures | | | | | | | | | |
|---|---|---|---|---|---|---|---|---|---|---|
| | | | | | | PCGL | | | | |
| | | | | PCGL | | doping | | | | |
| | Total | | | doping | | material 2 | Ratio of | | | Thickness |
| | thickness | | Ratio of | material 1 | Ratio of | (second | PCGL | | | of thin |
| | of charge | PCGL | PCGL | (first hole | PCGL | hole | doping | Thickness | Thin | layer |
| Device | generation | host | host | injection | doping | injection | material | of PCGL | layer | material |
| number | layer(Å) | material | material | material) | material 1 | material) | 2 | layer (Å) | material | (Å) |
| Embodiment | 240 | C54 | 90% | B10 | 6% | A5 | 4% | 120 | / | / |
| 1 | | | | | | | | | | |
| Embodiment | 240 | C52 | 90% | B10 | 6% | A5 | 4% | 120 | / | / |
| 2 | | | | | | | | | | |
| Embodiment | 240 | C45 | 88% | B10 | 6% | A5 | 6% | 120 | / | / |
| 3 | | | | | | | | | | |
| Embodiment | 240 | C35 | 88% | B10 | 6% | A5 | 6% | 120 | / | / |
| 4 | | | | | | | | | | |
| Embodiment | 240 | C54 | 90% | B20 | 6% | A5 | 4% | 120 | / | / |
| 5 | | | | | | | | | | |
| Embodiment | 240 | C54 | 90% | B10 | 6% | A7 | 4% | 120 | / | / |
| 6 | | | | | | | | | | |
| Embodiment | 240 | C54 | 90% | B10 | 4% | A5 | 6% | 120 | / | / |
| 7 | | | | | | | | | | |
| Embodiment | 240 | C54 | 90% | B10 | 6% | A5 | 4% | 110 | A5 | 10 |
| 8 | | | | | | | | | | |
| Embodiment | 240 | C52 | 90% | B10 | 6% | A5 | 4% | 110 | A5 | 10 |
| 9 | | | | | | | | | | |
| Embodiment | 240 | C45 | 88% | B10 | 6% | A5 | 6% | 110 | A5 | 10 |
| 10 | | | | | | | | | | |
| Embodiment | 240 | C54 | 90% | B10 | 6% | A7 | 4% | 110 | A7 | 10 |
| 11 | | | | | | | | | | |
| Embodiment | 240 | C54 | 90% | B10 | 6% | A5 | 4% | 114 | A5 | 6 |
| 12 | | | | | | | | | | |
| Embodiment | 240 | C54 | 90% | B10 | 6% | A5 | 4% | 110 | NCGL-1 | 10 |
| 13 | | | | | | | | | | |
| Embodiment | 240 | C52 | 90% | B10 | 6% | A5 | 4% | 110 | NCGL-1 | 10 |
| 14 | | | | | | | | | | |
| Embodiment | 240 | C54 | 90% | B10 | 6% | A5 | 4% | 100 | dual thin | each 10 |
| 15 | | | | | | | | | layers of | |
| | | | | | | | | | NCGL-1 | |
| | | | | | | | | | and A5 | |
| Embodiment | 240 | C52 | 90% | B10 | 6% | A5 | 4% | 100 | dual thin | each 10 |
| 16 | | | | | | | | | layers of | |
| | | | | | | | | | NCGL-1 | |
| | | | | | | | | | and A5 | |
| Comparative | 240 | C54 | 94% | B10 | 6% | / | / | 120 | / | / |
| Example 1 | | | | | | | | | | |
| Comparative | 240 | C54 | 90% | B10 | 10% | / | / | 120 | / | / |
| Example 2 | | | | | | | | | | |
| Comparative | 240 | C54 | 90% | B10 | 10% | / | / | 110 | NCGL-1 | 10 |
| Example 3 | | | | | | | | | | |

It should be noted that in each of the above embodiments and comparative examples, the PCGL host material denotes the hole transport material included in the P-type charge generation sub-layer; the PCGL doping material 1 denotes the first hole injection material; the PCGL doping material 2 denotes the second hole injection material; the NCGL-1 denotes the second electron transport material; the thin layer material denotes the first intermediate sub-layer, the second intermediate sub-layer, or the first intermediate sub-layer and the second intermediate sub-layer.

It should be noted that the first intermediate sub-layer is not provided in Embodiments 1 to 7, that is, Embodiments 1 to 7 are specific experimental embodiments illustrated in FIG. 2.

It should be noted that the first intermediate sub-layer is provided in Embodiments 8 to 12, that is, Embodiments 8 to 12 are specific experimental embodiments illustrated in FIG. 3.

It should be noted that the first intermediate sub-layer is provided but the second intermediate sub-layer is not provided in Embodiments 13 and 14, that is, Embodiments 13 and 14 are specific experimental embodiments illustrated in FIG. 4.

It should be noted that both the first intermediate sub-layer and the second intermediate sub-layer are provided in Embodiments 15 and 16, that is, Embodiments 15 and 16 are specific experimental embodiments illustrated in FIG. 5.

### Device Performance Measurement

1) Measurement of operating voltage and current efficiency: the tandem organic light-emitting devices prepared in the embodiments and comparative examples are tested using a Keithley 2365A digital nanovoltmeter to measure the current of the devices of the respective embodiments and comparative examples at different voltages, and then the current density of the devices at different voltages was calculated by dividing the current by the light-emitting area. The brightness and radiant energy flux density of the devices at different voltages are measured using a Konicaminolta CS-2000 spectroradiometer. Based on the current density and brightness of the device at different voltages, the operating voltage V and current efficiency BI (Cd/A/CIEy) at the same current density (10 mA/cm²) are obtained.

The operating voltage measured in Comparative Example 1 was defined as 100%. The value of the operating voltage of an embodiment or comparative example=operating voltage of the embodiment/operating voltage of Comparative Example 1×100%.

The current efficiency measured in Comparative Example 1 was defined as 100%. The value of the current efficiency of an embodiment or comparative example=current efficiency of the embodiment or comparative example/current efficiency of Comparative Example 1×100%.

A lower operating voltage means that the device requires less electrical power when operating under the same conditions, which can reduce power consumption, improve energy efficiency, and extend the battery's lifetime.

The current efficiency refers to the amount of light output or effective output in other forms that a device can produce under a given current input. High current efficiency means that the device can output more light or achieve higher performance when the same current is input.
2) Drift voltage of the device: the high temperature lifetime LT95 of the device was measured at 30 mA/cm² and 85° C. The drift voltage (ΔV, the difference of the operating voltages of the device before and after the lifetime, ΔV-operating voltage after lifetime-operating voltage before lifetime, which is in units of V) of the device was calculated based on the operating voltages of the device before and after the lifetime LT95. The magnitude of the drift voltage of Comparative Example 1 was defined as 100%, and the value of the drift voltage of an embodiment or comparative example=drift voltage of the embodiment or comparative example/drift voltage of Comparative Example 1×100%. The magnitude of the drift voltage reflects the stability of the device.
3) Testing of lateral leakage current: the glass substrate of the tandem organic light-emitting device in the above embodiment or comparative example was replaced with a substrate with a structure as shown in FIG. 10 (FIG. 10 is a schematic diagram of a substrate structure selected for leakage current testing according to some embodiments of the present application) for preparation. FIG. 10 is referenced to for the local morphology of the substrate, where the pattern-filled area is a deposition area 700 for depositing the tandem organic light-emitting devices, and the deposition area 700 is a solid part. The white-filled area is a hollow area 800 of the substrate main body. After the device was prepared, a voltage ranging from −10V to +10V was applied across the two electrodes (anode and cathode), and the current of the devices of the embodiments and comparative examples each was tested at different voltages using a Keithley 2365A digital nanovoltmeter. The magnitude of the leakage current of Comparative Example 1 at 10V was defined as 100%, and the value of the leakage current of an embodiment or comparative example (the relative magnitude of the leakage current under the same conditions)=leakage current of the embodiment or comparative example/leakage current of Comparative Example 1×100%. The device performance results are obtained as shown in Table 2.

TABLE 2
Device performance results in each embodiment
and each comparative example

| | Device performance | | | | |
|---|---|---|---|---|---|
| | | | | Relative | Relative |
| | | | | magnitude of | magnitude of |
| Device | Voltage | BI | LT 95 | drift | leakage |
| number | (%) | (%) | (%) | voltage (%) | current (%) |
| Embodiment 1 | 97 | 103.5 | 104.1 | 101.2 | 99.3 |
| Embodiment 2 | 96.7 | 102.8 | 105.1 | 99.7 | 101.2 |
| Embodiment 3 | 96.5 | 103.7 | 103.9 | 102.1 | 101.8 |
| Embodiment 4 | 97.1 | 102.5 | 104.2 | 102.5 | 100.5 |
| Embodiment 5 | 96.6 | 102.2 | 104.4 | 101.6 | 101.2 |
| Embodiment 6 | 97.4 | 103.6 | 102.7 | 98.2 | 98.4 |
| Embodiment 7 | 96.2 | 100.8 | 106.3 | 97.3 | 101.9 |
| Embodiment 8 | 97 | 103.3 | 104.3 | 101.1 | 73.6 |
| Embodiment 9 | 96.7 | 102.6 | 105.4 | 99.7 | 75.2 |
| Embodiment 10 | 96.5 | 103.9 | 103.6 | 102.1 | 70.3 |
| Embodiment 11 | 97.3 | 103.8 | 102.4 | 98.2 | 67.1 |
| Embodiment 12 | 97.3 | 102 | 103.1 | 102.5 | 66.5 |
| Embodiment 13 | 97.1 | 103.2 | 104.6 | 73.2 | 99.8 |
| Embodiment 14 | 96.9 | 103.4 | 105.3 | 70.6 | 101.6 |
| Embodiment 15 | 97.1 | 103.5 | 104 | 68.5 | 73.6 |
| Embodiment 16 | 97 | 103 | 105.5 | 69.8 | 71.1 |
| Comparative | 100 | 100 | 100 | 100 | 100 |
| Example 1 | | | | | |
| Comparative | 99.1 | 101.2 | 100.9 | 106.7 | 103.8 |
| Example 2 | | | | | |
| Comparative | 99.1 | 101.2 | 100.9 | 83.6 | 103.8 |
| Example 3 | | | | | |

Analysis result 1: based on the data of Embodiments 1 to 7 and Comparative Examples 1 to 2, it can be seen that in the light-emitting devices of Embodiments 1 to 7 (the light-emitting devices illustrated in FIG. 2) where the P-type charge generation sub-layer 32 includes the hole transport material, and the first hole injection material and the second hole injection material doped into the hole transport material (i.e., the P-type charge generation sub-layer adopts the PCGL host material and the dual hole injection materials doped at an appropriate ratio), Embodiments 1 to 7 exhibit a lower operating voltage and a higher current efficiency. This indicates that the use of the present solution can enhance the performance of the device and is thus expected to significantly lower the power consumption of the device.
Analysis result 2: compared with Embodiment 1, in the light-emitting devices of Embodiments 8 to 12 (the light-emitting devices illustrated in FIG. 3) where the first intermediate sub-layer is further disposed (i.e., the P-type charge generation sub-layer adopts the PCGL host material and the dual hole injection materials doped at an appropriate ratio, and further comprises a PD thin layer), in addition to the lower operating voltage and higher current efficiency, a smaller lateral leakage current is also achieved, further enhancing the overall performance of the device.
Analysis result 3: compared with Embodiment 1, in the light-emitting devices of Embodiment 13 to 14 (the light-emitting devices illustrated in FIG. 4) where a second intermediate sub-layer is further disposed (i.e., the P-type charge generation sub-layer adopts the PCGL host material and the dual hole injection materials doped at an appropriate ratio, and further comprises an NCGL-1 thin layer), in addition to the lower operating voltage and higher current efficiency, a smaller drift voltage is also achieved, further enhancing the stability of the device.
Analysis result 4: compared with Embodiment 1, in the light-emitting devices of Embodiments 15 to 16 (the light-emitting device illustrated in FIG. 5) where the first intermediate sub-layer and the second intermediate sub-layer are further disposed (i.e., the P-type charge generation sub-layer adopts the PCGL host material and the dual hole injection materials doped at an appropriate ratio, and further comprises both an NCGL-1 thin layer and a PD thin layer), in addition to the lower operating voltage and higher current efficiency, a smaller drift voltage and a smaller lateral leakage current are also achieved, which not only lowers the power consumption and lateral leakage of the device, but also enhances the stability of the device, thereby significantly optimizing the overall performance of the device.

Although the present invention has been described with reference to the preferred embodiments thereof, various modifications may be made thereto and the components may be replaced with equivalents without departing from the scope of the present invention. In particular, the technical features mentioned in various embodiments can be combined in any manner as long as there is no structural conflict. The present invention is not limited to the embodiments disclosed herein, but includes all technical solutions falling within the scope of the claims.

Various technical features of the aforementioned embodiments can be freely combined. For a brief description, not all possible combinations of the technical features in the aforementioned embodiments are described. However, the combinations of these technical features should be considered to fall within the scope of the present description as long as there is no conflict among these technical features.

The above embodiments merely express several implementations of the present application, and their descriptions are relatively specific and detailed, but they cannot therefore be construed as limiting the scope of the invention. It should be pointed out that those skilled in the art can make various transformations and improvements without departing from the concept of the present application, and all of these fall within the protection scope of the present application. Therefore, the scope of protection of the present application shall be subject to the appended claims.

What is claimed is:

1. A light-emitting device, comprising:
an anode,
a cathode,
a first light-emitting unit and a second light-emitting unit which are located between the anode and the cathode, and
at least one charge generation layer located between the first light-emitting unit and the second light-emitting unit, the charge generation layer comprising an N-type charge generation sub-layer and a P-type charge generation sub-layer located on a side of the N-type charge generation sub-layer close to the cathode, wherein the P-type charge generation sub-layer comprises a hole transport material, and a first hole injection material and a second hole injection material which are doped into the hole transport material, an absolute value of a lowest unoccupied molecular orbital energy level of the second hole injection material being less than that of the first hole injection material.

2. The light-emitting device according to claim 1, wherein the absolute value of the lowest unoccupied molecular orbital energy level of the second hole injection material is less than or equal to 4.8 eV, or
the absolute value of the lowest unoccupied molecular orbital energy level of the first hole injection material is greater than or equal to 4.8 eV.

3. The light-emitting device according to claim 1, wherein an absolute value of difference between the lowest unoccupied molecular orbital energy level of the first hole injection material and a highest occupied molecular orbital energy level of the hole transport material is less than or equal to 0.5 eV.

4. The light-emitting device according to claim 1, wherein an absolute value of the highest occupied molecular orbital energy level of the hole transport material is less than or equal to 5.2 eV.

5. The light-emitting device according to claim 1, wherein the N-type charge generation sub-layer comprises a first electron transport material, and an absolute value of a lowest unoccupied molecular orbital energy level of the N-type charge generation sub-layer is in a range of 1.58 eV to 2 eV.

6. The light-emitting device according to claim 1, wherein
a mass percentage of the hole transport material is in a range of 78% to 96%,
a mass percentage of the first hole injection material is in a range of 2% to 12%,
a mass percentage of the second hole injection material is in a range of 1% to 10%,
a thickness of the P-type charge generation sub-layer is in a range of 50 angstroms to 200 angstroms.

7. The light-emitting device according to claim 1, wherein the second hole injection material comprises at least one of following materials A1 to A39:

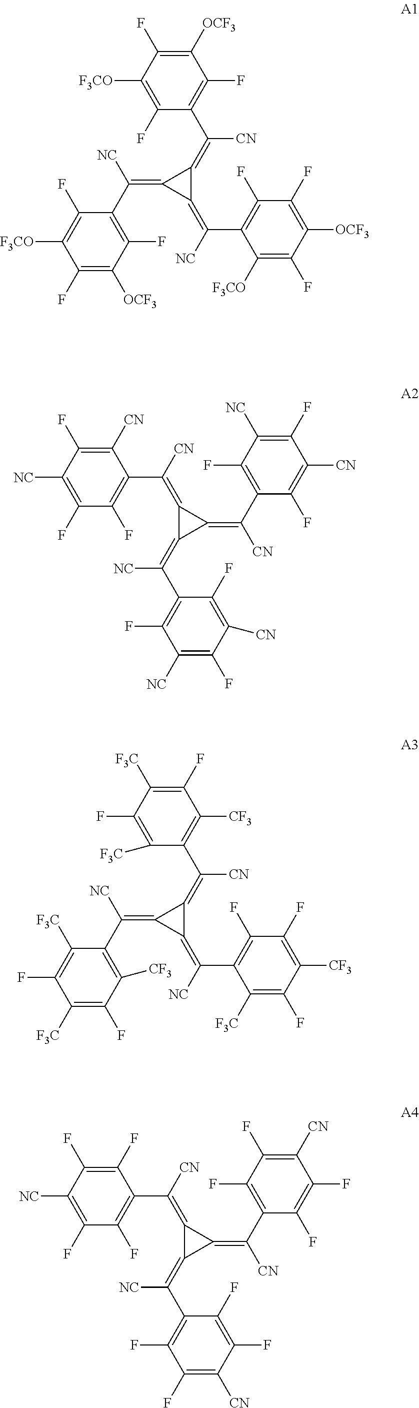

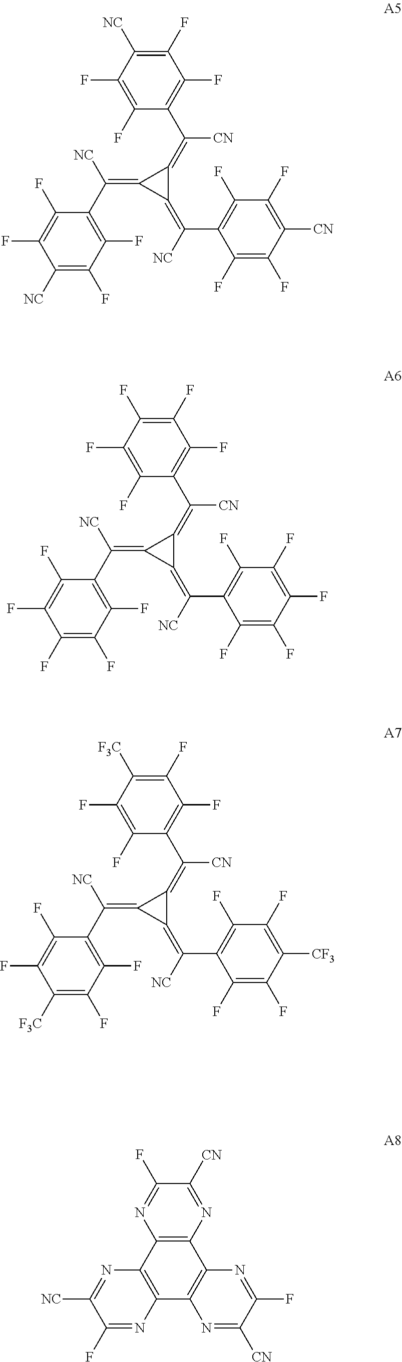 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(=C1C(=C(C#N)c2c(F)c(F)c(F)c(F)c2F)C1=C(C#N)c1c(F)c(F)c(F)c(F)c1F)c1c(F)c(F)c(F)c(F)c1F ; N#CC(=C1C(=C(C#N)c2c(F)c(F)c(C(F)(F)F)c(F)c2F)C1=C(C#N)c1c(F)c(F)c(C(F)(F)F)c(F)c1F)c1c(F)c(F)c(C(F)(F)F)c(F)c1F ; N#Cc1nc2c(nc1F)c1nc(C#N)c(F)nc1c1nc(C#N)c(F)nc21]

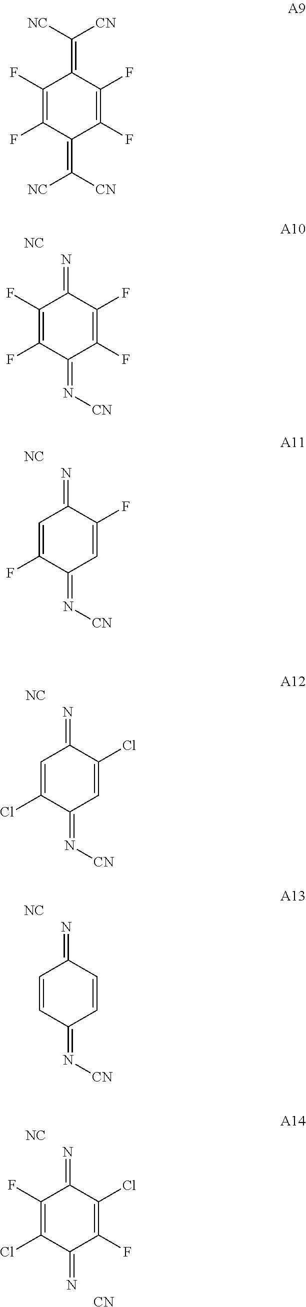

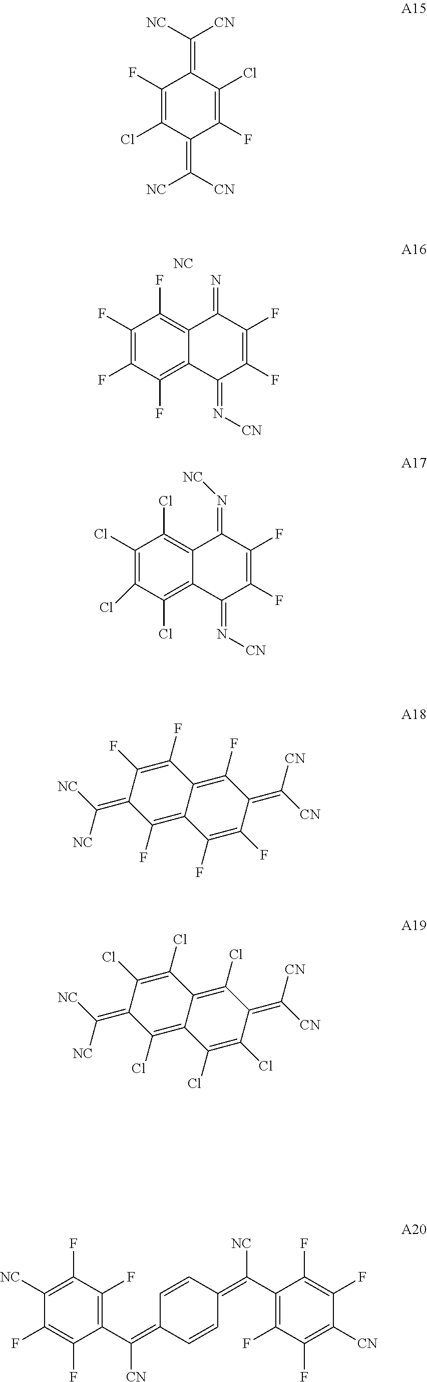

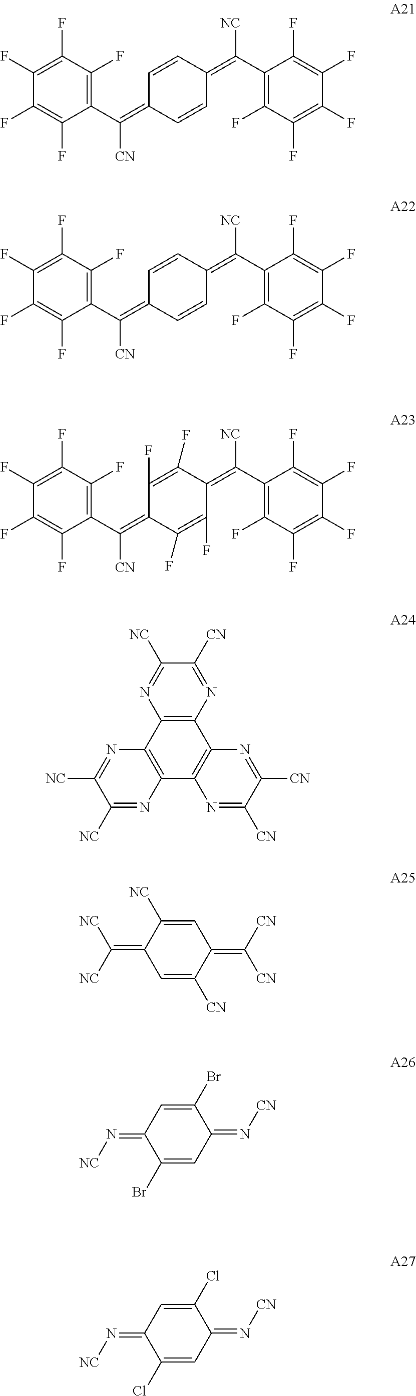

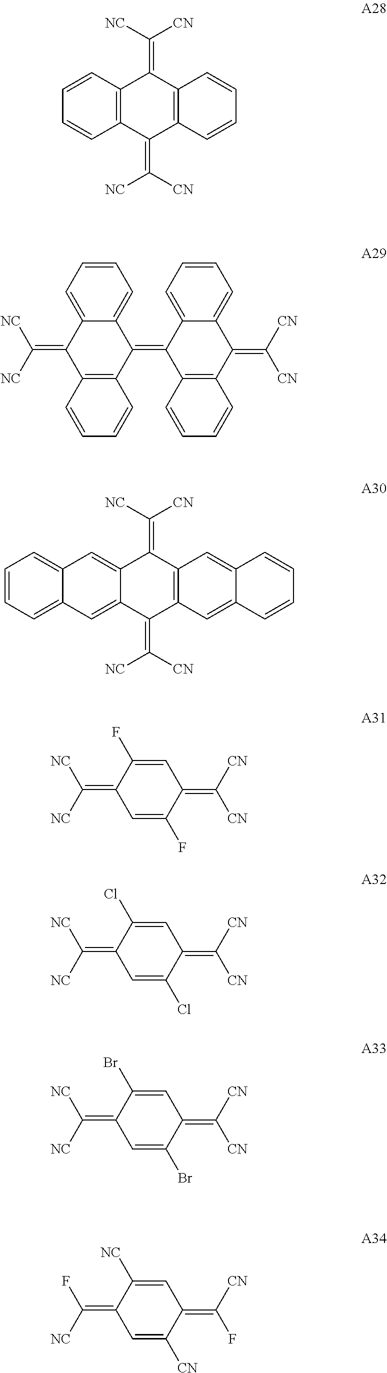

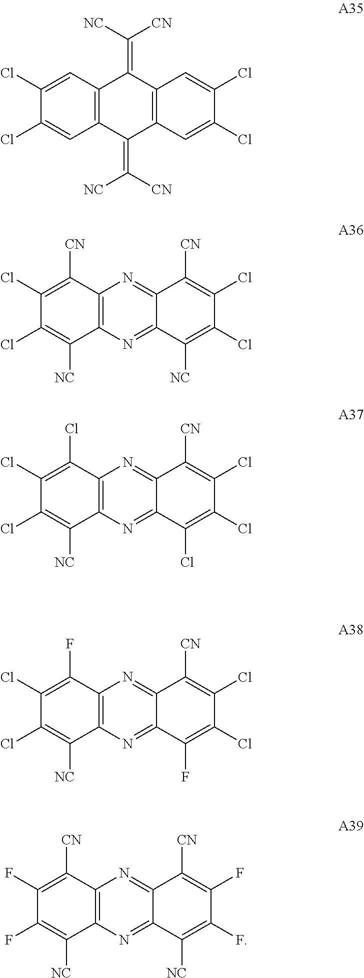 [SMILES: N#CC(C#N)=c1c2cc(Cl)c(Cl)cc2c(=C(C#N)C#N)c2cc(Cl)c(Cl)cc12 ; N#Cc1c(Cl)c(Cl)c(C#N)c2nc3c(C#N)c(Cl)c(Cl)c(C#N)c3nc12 ; N#Cc1c(Cl)c(Cl)c(Cl)c2nc3c(C#N)c(Cl)c(Cl)c(Cl)c3nc12 ; N#Cc1c(Cl)c(Cl)c(F)c2nc3c(C#N)c(Cl)c(Cl)c(F)c3nc12 ; N#Cc1c(F)c(F)c(C#N)c2nc3c(C#N)c(F)c(F)c(C#N)c3nc12]

8. The light-emitting device according to claim 1, wherein the first hole injection material comprises a compound represented by Formula 1: 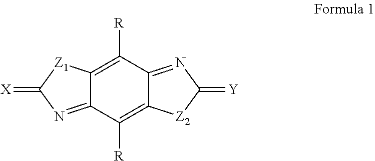
where X and Y are each independently selected from CR″R″ ′, NR′, O, S or Se;
where Z₁ and Z₂ are each independently selected from O, S or Se;
in which R, R′, R″ and R′″ are each independently selected from the group consisting of hydrogen, deuterium, halogen, nitroso, nitro, acyl, carbonyl, carboxyl, ester, cyano, isocyano, SCN, OCN, SF5, boryl, sulfinyl, sulfonyl, phosphinoxy, substituted or unsubstituted alkyl containing 1 to 20 carbon atoms, substituted or unsubstituted cycloalkyl containing 3 to 20 ring carbon atoms, substituted or unsubstituted heteroalkyl containing 1 to 20 carbon atoms, substituted or unsubstituted aralkyl containing 7 to 30 carbon atoms, substituted or unsubstituted alkoxy containing 1 to 20 carbon atoms, substituted or unsubstituted aryloxy containing 6 to 30 carbon atoms, substituted or unsubstituted alkenyl containing 2 to 20 carbon atoms, substituted or unsubstituted alkynyl containing 2 to 20 carbon atoms, substituted or unsubstituted aryl containing 6 to 30 carbon atoms, substituted or unsubstituted heteroaryl containing 3 to 30 carbon atoms, substituted or unsubstituted alkylsilyl containing 3 to 20 carbon atoms, substituted or unsubstituted arylsilyl containing 6 to 20 carbon atoms, and combinations thereof; in which each R is the same or different, and at least one of R, R′, R″ and R′″ is a group having at least one electron-withdrawing moiety; and
adjacent substituents are optionally connected to form a ring.

9. The light-emitting device according to claim 1, wherein the first hole injection material comprises at least one of following B1 to B30:

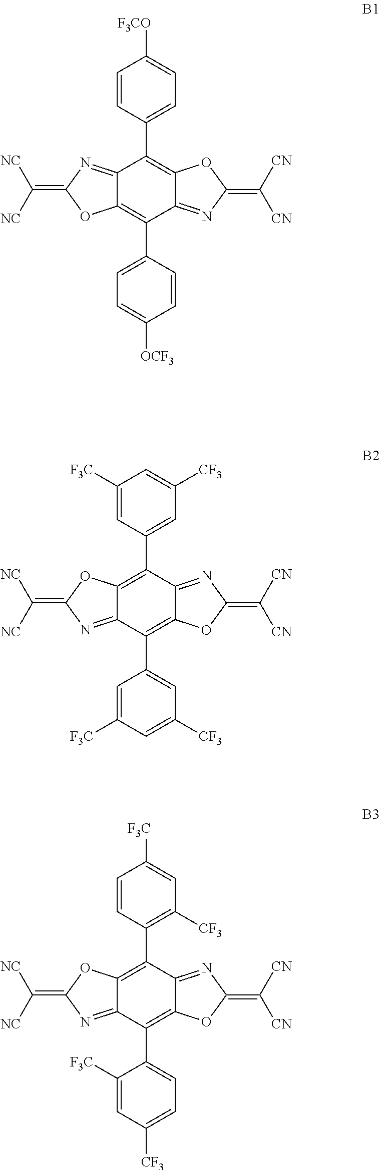 [SMILES: N#CC(C#N)=c1nc2c(-c3ccc(OC(F)(F)F)cc3)c3oc(=C(C#N)C#N)nc3c(-c3ccc(OC(F)(F)F)cc3)c2o1 ; N#CC(C#N)=c1nc2c(-c3cc(C(F)(F)F)cc(C(F)(F)F)c3)c3oc(=C(C#N)C#N)nc3c(-c3cc(C(F)(F)F)cc(C(F)(F)F)c3)c2o1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1]

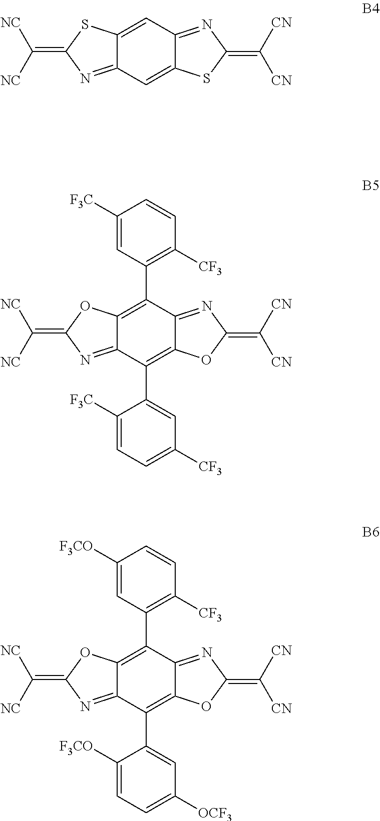 [SMILES: N#CC(C#N)=c1nc2cc3sc(=C(C#N)C#N)nc3cc2s1 ; N#CC(C#N)=c1nc2c(-c3cc(C(F)(F)F)ccc3C(F)(F)F)c3oc(=C(C#N)C#N)nc3c(-c3cc(C(F)(F)F)ccc3C(F)(F)F)c2o1 ; N#CC(C#N)=c1nc2c(-c3cc(OC(F)(F)F)ccc3C(F)(F)F)c3oc(=C(C#N)C#N)nc3c(-c3cc(OC(F)(F)F)ccc3OC(F)(F)F)c2o1]

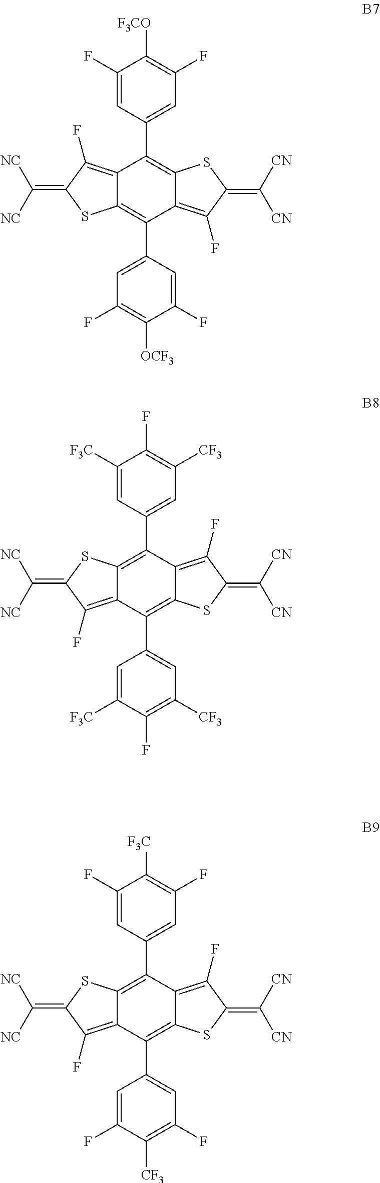 [SMILES: N#CC(C#N)=c1sc2c(-c3cc(F)c(OC(F)(F)F)c(F)c3)c3c(F)c(=C(C#N)C#N)sc3c(-c3cc(F)c(OC(F)(F)F)c(F)c3)c2c1F ; N#CC(C#N)=c1sc2c(-c3cc(C(F)(F)F)c(F)c(C(F)(F)F)c3)c3c(F)c(=C(C#N)C#N)sc3c(-c3cc(C(F)(F)F)c(F)c(C(F)(F)F)c3)c2c1F ; N#CC(C#N)=c1sc2c(-c3cc(F)c(C(F)(F)F)c(F)c3)c3c(F)c(=C(C#N)C#N)sc3c(-c3cc(F)c(C(F)(F)F)c(F)c3)c2c1F]

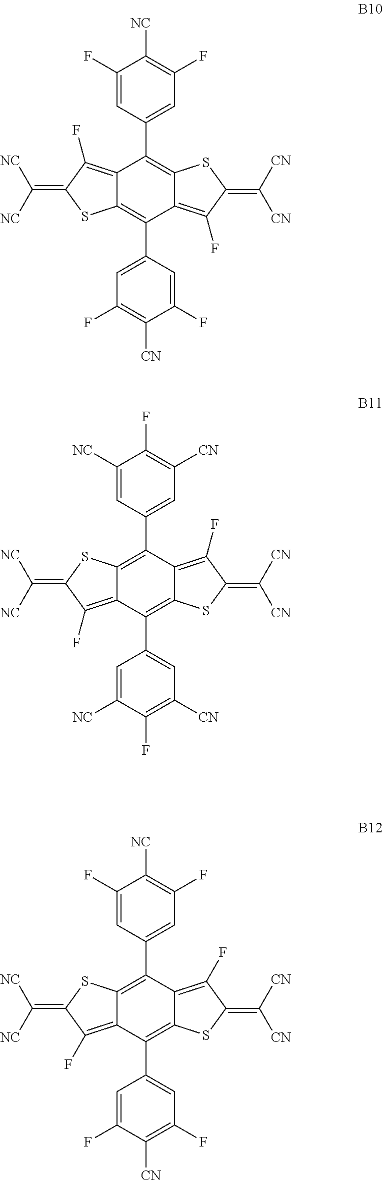 [SMILES: N#CC(C#N)=c1sc2c(-c3cc(F)c(C#N)c(F)c3)c3c(F)c(=C(C#N)C#N)sc3c(-c3cc(F)c(C#N)c(F)c3)c2c1F ; N#CC(C#N)=c1sc2c(-c3cc(C#N)c(F)c(C#N)c3)c3c(F)c(=C(C#N)C#N)sc3c(-c3cc(C#N)c(F)c(C#N)c3)c2c1F ; N#CC(C#N)=c1sc2c(-c3cc(F)c(C#N)c(F)c3)c3c(F)c(=C(C#N)C#N)sc3c(-c3cc(F)c(C#N)c(F)c3)c2c1F]

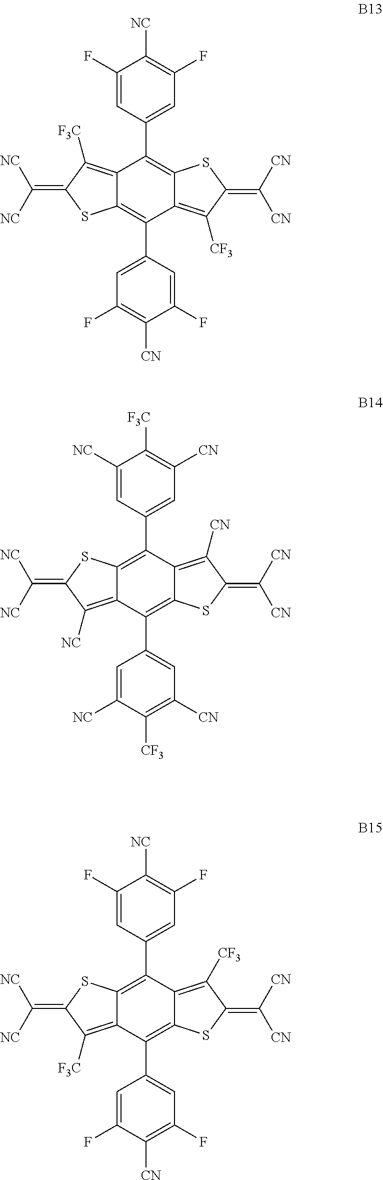 [SMILES: N#CC(C#N)=c1sc2c(-c3cc(F)c(C#N)c(F)c3)c3c(C(F)(F)F)c(=C(C#N)C#N)sc3c(-c3cc(F)c(C#N)c(F)c3)c2c1C(F)(F)F ; N#CC(C#N)=c1sc2c(-c3cc(C#N)c(C(F)(F)F)c(C#N)c3)c3c(C#N)c(=C(C#N)C#N)sc3c(-c3cc(C#N)c(C(F)(F)F)c(C#N)c3)c2c1C#N ; N#CC(C#N)=c1sc2c(-c3cc(F)c(C#N)c(F)c3)c3c(C(F)(F)F)c(=C(C#N)C#N)sc3c(-c3cc(F)c(C#N)c(F)c3)c2c1C(F)(F)F]

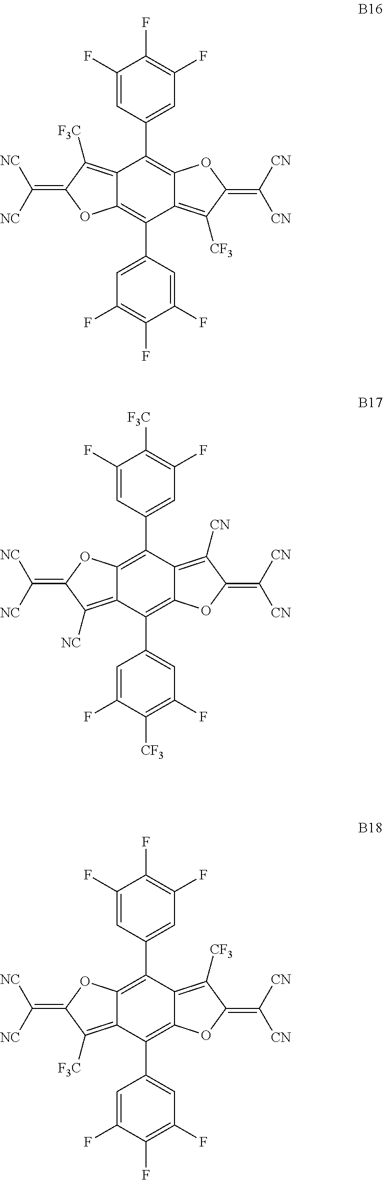 [SMILES: N#CC(C#N)=c1oc2c(-c3cc(F)c(F)c(F)c3)c3c(C(F)(F)F)c(=C(C#N)C#N)oc3c(-c3cc(F)c(F)c(F)c3)c2c1C(F)(F)F ; N#CC(C#N)=c1oc2c(-c3cc(F)c(C(F)(F)F)c(F)c3)c3c(C#N)c(=C(C#N)C#N)oc3c(-c3cc(F)c(C(F)(F)F)c(F)c3)c2c1C#N ; N#CC(C#N)=c1oc2c(-c3cc(F)c(F)c(F)c3)c3c(C(F)(F)F)c(=C(C#N)C#N)oc3c(-c3cc(F)c(F)c(F)c3)c2c1C(F)(F)F]

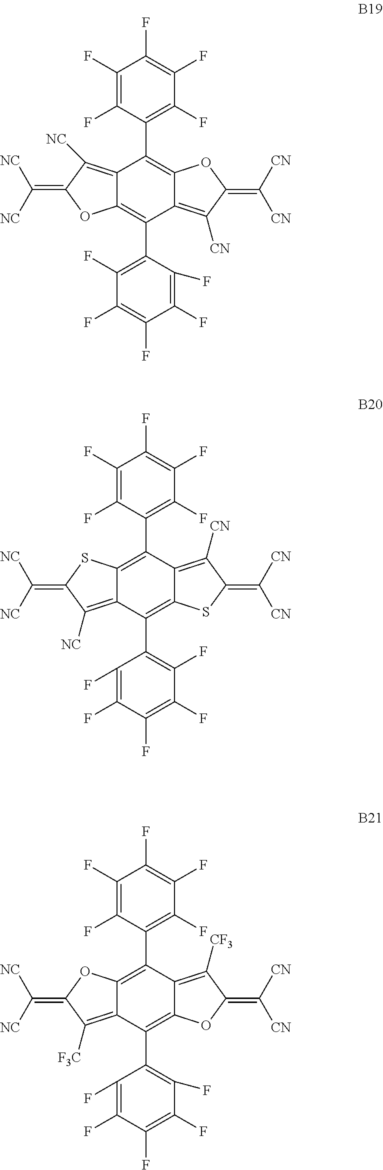 [SMILES: N#CC(C#N)=c1oc2c(-c3c(F)c(F)c(F)c(F)c3F)c3c(C#N)c(=C(C#N)C#N)oc3c(-c3c(F)c(F)c(F)c(F)c3F)c2c1C#N ; N#CC(C#N)=c1sc2c(-c3c(F)c(F)c(F)c(F)c3F)c3c(C#N)c(=C(C#N)C#N)sc3c(-c3c(F)c(F)c(F)c(F)c3F)c2c1C#N ; N#CC(C#N)=c1oc2c(-c3c(F)c(F)c(F)c(F)c3F)c3c(C(F)(F)F)c(=C(C#N)C#N)oc3c(-c3c(F)c(F)c(F)c(F)c3F)c2c1C(F)(F)F]

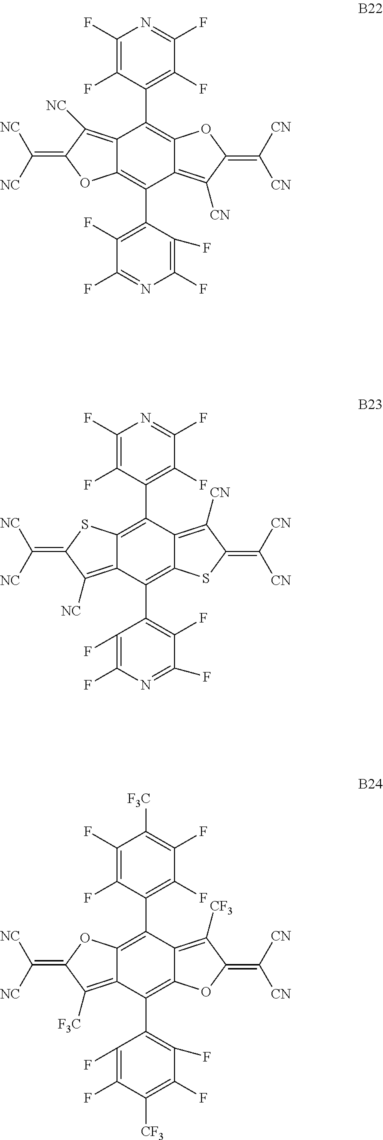 [SMILES: N#CC(C#N)=c1oc2c(-c3c(F)c(F)nc(F)c3F)c3c(C#N)c(=C(C#N)C#N)oc3c(-c3c(F)c(F)nc(F)c3F)c2c1C#N ; N#CC(C#N)=c1sc2c(-c3c(F)c(F)nc(F)c3F)c3c(C#N)c(=C(C#N)C#N)sc3c(-c3c(F)c(F)nc(F)c3F)c2c1C#N ; N#CC(C#N)=c1oc2c(-c3c(F)c(F)c(C(F)(F)F)c(F)c3F)c3c(C(F)(F)F)c(=C(C#N)C#N)oc3c(-c3c(F)c(F)c(C(F)(F)F)c(F)c3F)c2c1C(F)(F)F]

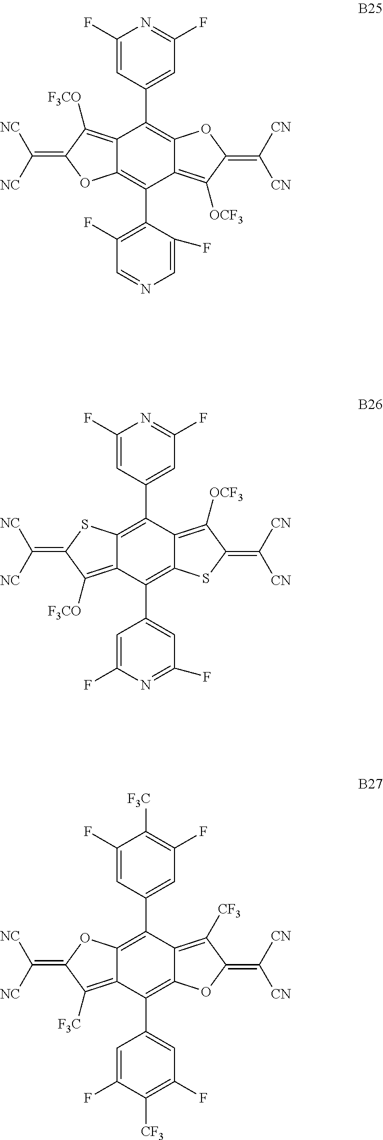 [SMILES: N#CC(C#N)=c1oc2c(-c3c(F)cncc3F)c3c(OC(F)(F)F)c(=C(C#N)C#N)oc3c(-c3cc(F)nc(F)c3)c2c1OC(F)(F)F ; N#CC(C#N)=c1sc2c(-c3cc(F)nc(F)c3)c3c(OC(F)(F)F)c(=C(C#N)C#N)sc3c(-c3cc(F)nc(F)c3)c2c1OC(F)(F)F ; N#CC(C#N)=c1oc2c(-c3cc(F)c(C(F)(F)F)c(F)c3)c3c(C(F)(F)F)c(=C(C#N)C#N)oc3c(-c3cc(F)c(C(F)(F)F)c(F)c3)c2c1C(F)(F)F]

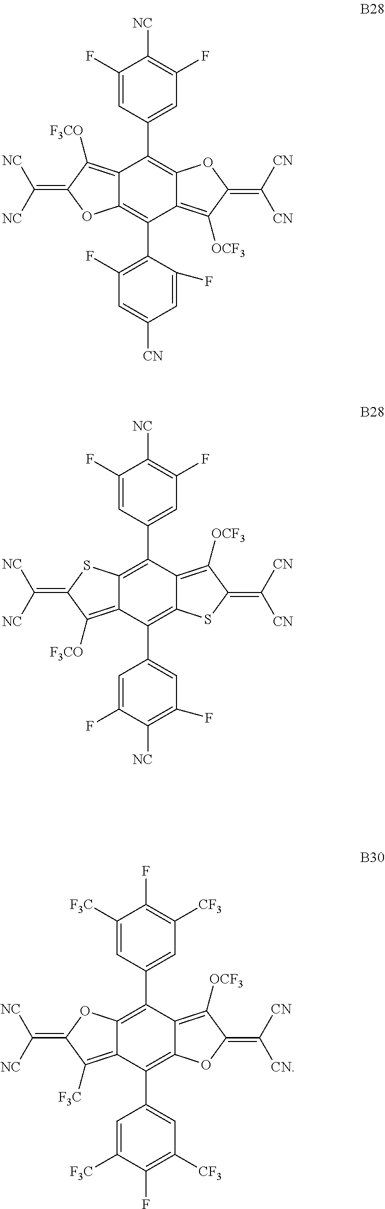 [SMILES: N#CC(C#N)=c1oc2c(-c3c(F)cc(C#N)cc3F)c3c(OC(F)(F)F)c(=C(C#N)C#N)oc3c(-c3cc(F)c(C#N)c(F)c3)c2c1OC(F)(F)F ; N#CC(C#N)=c1sc2c(-c3cc(F)c(C#N)c(F)c3)c3c(OC(F)(F)F)c(=C(C#N)C#N)sc3c(-c3cc(F)c(C#N)c(F)c3)c2c1OC(F)(F)F ; N#CC(C#N)=c1oc2c(-c3cc(C(F)(F)F)c(F)c(C(F)(F)F)c3)c3c(C(F)(F)F)c(=C(C#N)C#N)oc3c(-c3cc(C(F)(F)F)c(F)c(C(F)(F)F)c3)c2c1OC(F)(F)F]

10. The light-emitting device according to claim 1, wherein the hole transport material comprised in the P-type charge generation sub-layer comprises at least one of C1 to C55:

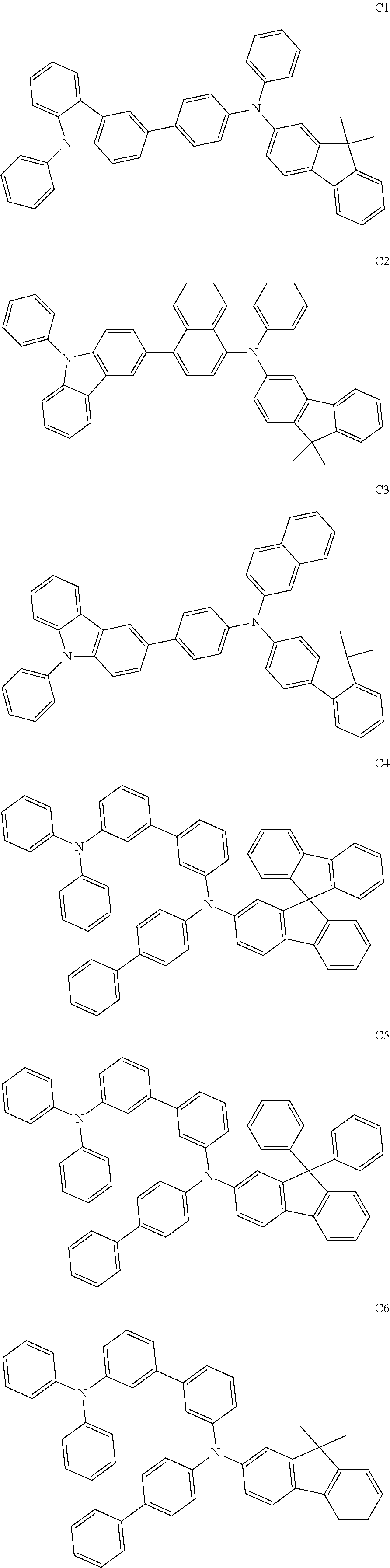

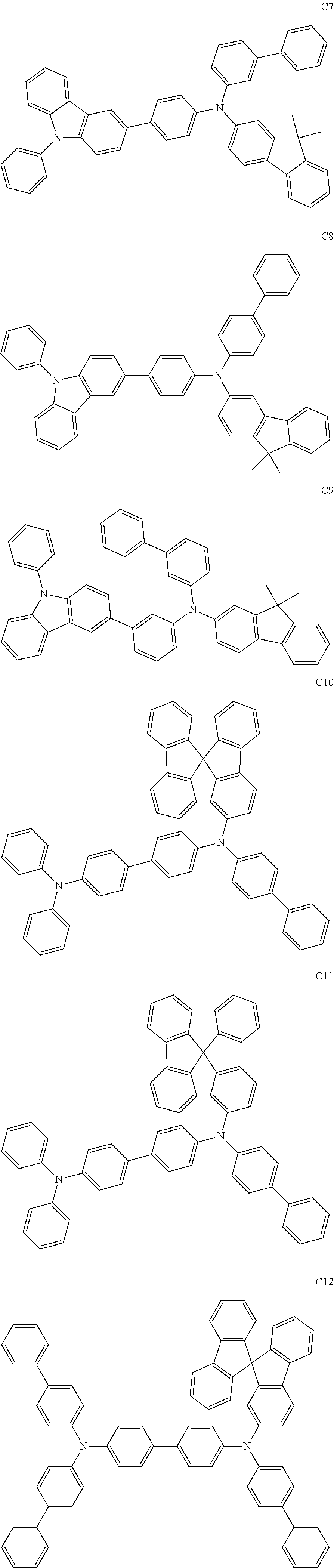

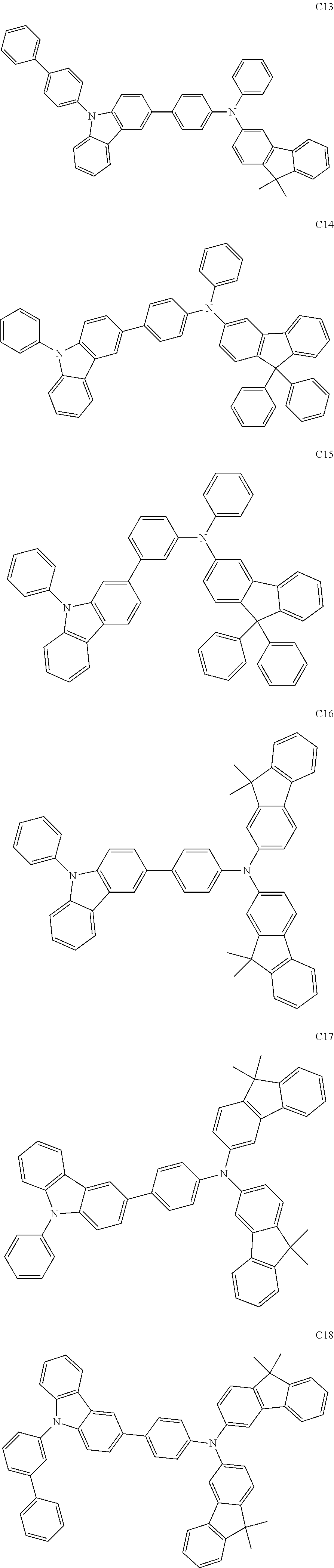

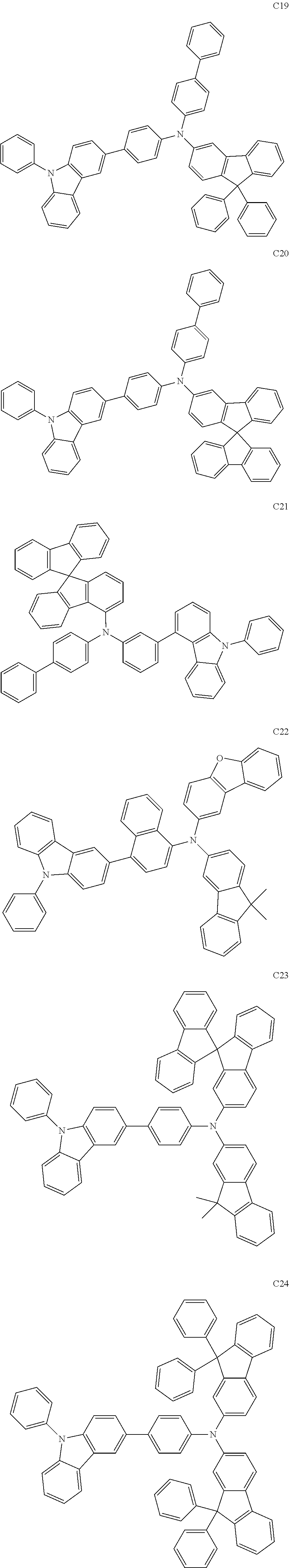

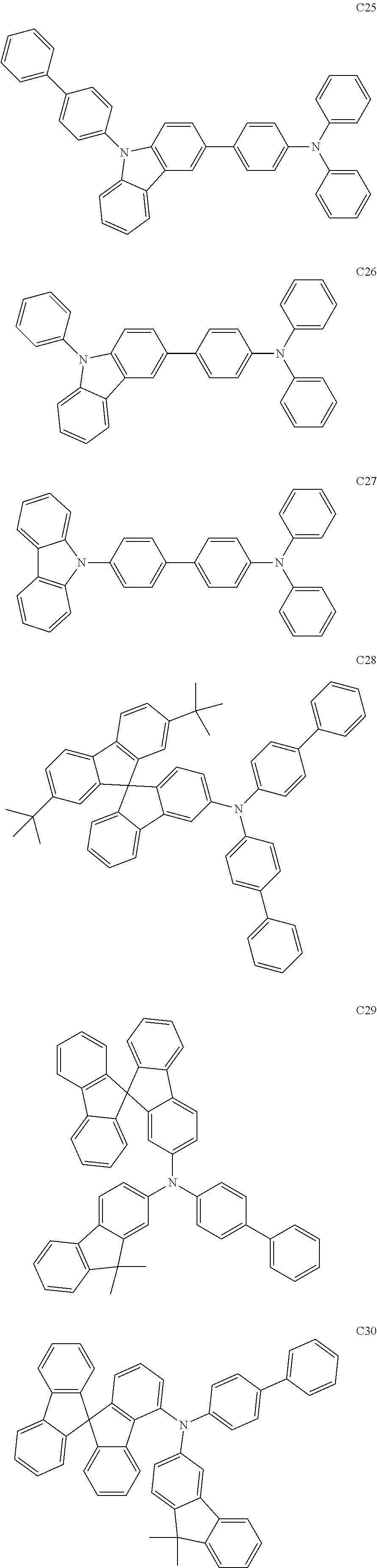 [SMILES: c1ccc(-c2ccc(-n3c4ccccc4c4cc(-c5ccc(N(c6ccccc6)c6ccccc6)cc5)ccc43)cc2)cc1 ; c1ccc(N(c2ccccc2)c2ccc(-c3ccc4c(c3)c3ccccc3n4-c3ccccc3)cc2)cc1 ; c1ccc(N(c2ccccc2)c2ccc(-c3ccc(-n4c5ccccc5c5ccccc54)cc3)cc2)cc1 ; CC(C)(C)c1ccc2c(c1)C1(c3ccccc3-c3cc(N(c4ccc(-c5ccccc5)cc4)c4ccc(-c5ccccc5)cc4)ccc31)c1cc(C(C)(C)C)ccc1-2 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2cc(N(c3ccc(-c4ccccc4)cc3)c3cccc4c3-c3ccccc3C43c4ccccc4-c4ccccc43)ccc21]

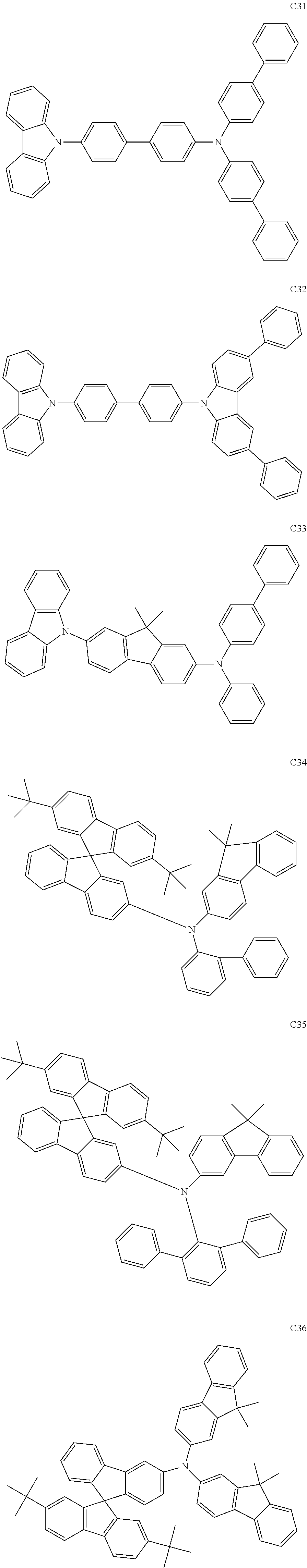

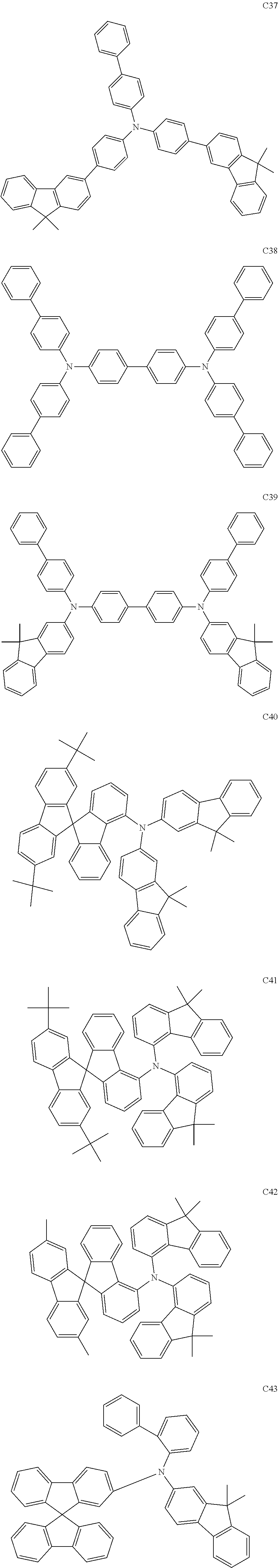

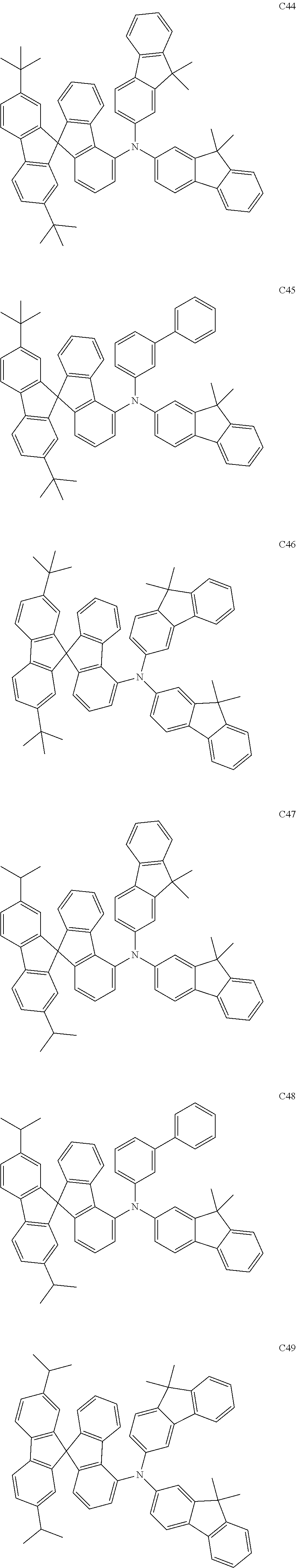

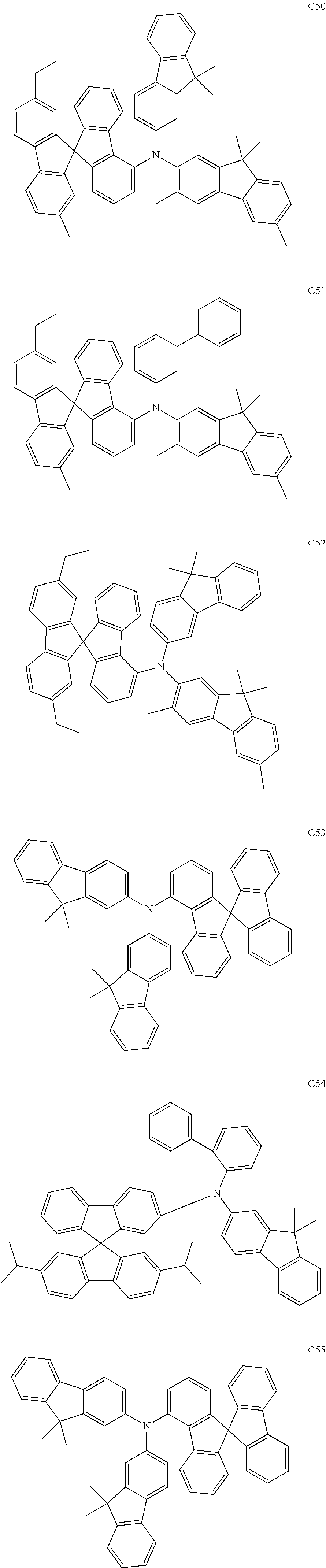

11. The light-emitting device according to claim 1, wherein the charge generation layer further comprises a first intermediate sub-layer disposed between the P-type charge generation sub-layer and the N-type charge generation sub-layer, the first intermediate sub-layer comprising a third hole injection material, and an absolute value of a lowest unoccupied molecular orbital energy level of the third hole injection material being less than that of the first hole injection material.

12. The light-emitting device according to claim 11, wherein the third hole injection material and the second hole injection material are the same.

13. The light-emitting device according to claim 11, wherein a thickness of the first intermediate sub-layer is less than or equal to 10 angstroms.

14. The light-emitting device according to claim 1, wherein the N-type charge generation sub-layer comprises a first electron transport material and an N-type dopant; and
the charge generation layer further comprises a second intermediate sub-layer disposed between the P-type charge generation sub-layer and the N-type charge generation sub-layer, the second intermediate sub-layer is disposed in contact with the N-type charge generation sub-layer, and the material of the second intermediate sub-layer is a second electron transport material.

15. The light-emitting device according to claim 14, wherein the second electron transport material and the first electron transport material are the same.

16. The light-emitting device according to claim 14, wherein a thickness of the second intermediate sub-layer is in a range of 5 angstroms to 20 angstroms.

17. A display panel comprising a light-emitting device which comprises:
an anode,
a cathode,
a first light-emitting unit and a second light-emitting unit which are located between the anode and the cathode, and
at least one charge generation layer located between the first light-emitting unit and the second light-emitting unit, the charge generation layer comprising an N-type charge generation sub-layer and a P-type charge generation sub-layer located on a side of the N-type charge generation sub-layer close to the cathode, wherein the P-type charge generation sub-layer comprises a hole transport material, and a first hole injection material and a second hole injection material which are doped into the hole transport material, an absolute value of a lowest unoccupied molecular orbital energy level of the second hole injection material being less than that of the first hole injection material.

18. A display device comprising the display panel which comprises a light-emitting device,
wherein the light-emitting device comprises: an anode,
a cathode,
a first light-emitting unit and a second light-emitting unit which are located between the anode and the cathode, and
at least one charge generation layer located between the first light-emitting unit and the second light-emitting unit, the charge generation layer comprising an N-type charge generation sub-layer and a P-type charge generation sub-layer located on a side of the N-type charge generation sub-layer close to the cathode, wherein the P-type charge generation sub-layer comprises a hole transport material, and a first hole injection material and a second hole injection material which are doped into the hole transport material, an absolute value of a lowest unoccupied molecular orbital energy level of the second hole injection material being less than that of the first hole injection material.
